(19) United States
(12) Patent Application Publication
(10) Pub. No.: US 2012/0301663 A1
(43) Pub. Date: Nov. 29, 2012

(54) CARBON NANOTUBE COMPOSITE AND METHOD FOR MAKING THE SAME

(75) Inventors: Yosuke Koike, Sagamihara-shi (JP); Eiji Nakashima, Obu-shi (JP); Gang Xie, Anjo-shi (JP)

(73) Assignee: AISIN SEIKI KABUSHIKI KAISHA, Aichi (JP)

(21) Appl. No.: 13/576,540

(22) PCT Filed: Mar. 10, 2011
(86) PCT No.: PCT/JP2011/001404

§ 371 Date: Aug. 1, 2012

(30) Foreign Application Priority Data
Mar. 26, 2010 (JP) 2010-072610
Dec. 24, 2010 (JP) 2010-288385

(51) Int. Cl. C23C 16/26; B32B 5/12; B82Y 40/00; B82Y 30/00

(52) U.S. Cl. 428/114; 427/249.1; 977/843; 977/742

(57) ABSTRACT

Disclosed are a carbon nanotube composite and a method for making the same advantageous for achieving a higher density of a carbon nanotube assembly. The carbon nanotube composite includes a substrate and a carbon nanotube assembly mounted on the surface of the substrate. The carbon nanotube assembly is composed of multiple carbon nanotubes arranged densely in parallel oriented in the direction upward from the surface of the substrate. The carbon nanotube assembly has a density of 70 mg/cm³ or more in a grown state.

### TECHNICAL FIELD

The present invention relates to a carbon nanotube composite and a method for making the same, the carbon nanotube composite includes an assembly of multiple carbon nanotubes oriented in the same direction.

### BACKGROUND ART

Carbon nanotube is a carbon material which is recently receiving attention. Patent Document 1 discloses a carbon nanotube composite made by subjecting a base plate to CVD-processing with the temperature of the base plate maintained at 675 to 750° C., thereby growing multiple carbon nanotubes on the surface of the base plate, the carbon nanotubes being arranged in parallel and almost perpendicular to the base plate.

Patent Document 2 discloses a carbon nanotube composite including a group of carbon nanotubes composed of multiple carbon nanotubes in the form of bristles formed on the surface of a base plate, and a metal film connecting the roots of the group of carbon nanotubes at the base plate side. According to the disclosure, a metal film having a higher melting point than the growth temperature of carbon nanotubes was formed, a catalyst is provided on the metal film. In this state, carbon nanotubes are grown from a source gas on the surface of the base plate, and then the metal is molten at a temperature higher than the growth temperature of the carbon nanotubes, followed by solidification, thereby coating and fixing the roots of the carbon nanotubes with the metal. Patent Document 3 discloses a structure of multilayer carbon nanotube assembly including multiple carbon nanotubes which are extremely densely arranged perpendicular to the surface of a silicon base plate.

Patent Document 4 discloses a technique for making a dense carbon nanotube assembly, including compressing a grown carbon nanotube assembly by secondary consolidation processing, which includes exposure to a liquid such as water, followed by drying. According to the method, a carbon nanotube assembly having a high density is obtained by subjecting grown carbon nanotubes to the secondary consolidation processing. Patent Document 4 also discloses a technique for achieving a high density of the carbon nanotube assembly by subjecting the carbon nanotube assembly to secondary consolidation processing including compression using a mechanical external pressure.
Patent Document 1: Japanese Unexamined Patent Application Publication No. 2001-220674
Patent Document 2: Japanese Unexamined Patent Application Publication No. 2007-76925
Patent Document 3: Japanese Unexamined Patent Application Publication No. 2008-120658
Patent Document 4: Japanese Unexamined Patent Application Publication No. 2007-182352

### DISCLOSURE OF INVENTION

### Problems to be Solved by the Invention

In industry, a carbon nanotube composite including a carbon nanotube assembly with a higher density is desired. However, the above-described techniques are not satisfactory for obtaining a carbon nanotube assembly with a high density. In Patent Document 3, the carbon nanotube assembly has a high density, but the density is not sufficiently high. According to Patent Document 4, the carbon nanotube assembly has a high density, but the achievement of the high density requires secondary processing including exposure of carbon nanotubes to water followed by drying, or compression of the carbon nanotube assembly by a mechanical external force.

The present invention has been accomplished in view of the above-described circumstances, and is intended to provide a carbon nanotube composite and a method for making the same which are advantageous for achieving a higher density of the carbon nanotube assembly composed of multiple carbon nanotubes arranged in parallel oriented in the same direction.

### Means for Solving the Problem

(1) The carbon nanotube composite according to a first aspect of the present invention includes a carbon nanotube assembly composed of multiple carbon nanotubes arranged densely in parallel oriented in the same direction, the carbon nanotube assembly having a high density of 70 mg/cm³ or more in a grown state. The high density of the carbon nanotube assembly is achieved in an as-grown state (at the time of completion of the growth of the carbon nanotubes) without undergoing secondary consolidation processing after the growth of the carbon nanotube assembly.

(2) The carbon nanotube composite according to a second aspect of the present invention includes (i) a substrate having a surface, and (ii) a carbon nanotube assembly having high density of 70 mg/cm³ or more which is mounted on the surface of the substrate and is composed of multiple carbon nanotubes densely arranged in parallel oriented in the same direction upward from the surface. The high density of the carbon nanotube assembly is achieved in the state of the growth of the carbon nanotube assembly (in an as-grown state, at the time of completion of the growth of the carbon nanotube assembly) without undergoing secondary consolidation processing after the growth of the carbon nanotube assembly. In this case, it is preferred that a catalyst be present between the carbon nanotube assembly and substrate. It is also preferred that a ground layer made of aluminum or an aluminum alloy be present between the catalyst and substrate. This is advantageous for obtaining multiple carbon nanotubes oriented in the same direction.

The method for making a carbon nanotube composite according the third aspect of the present invention includes steps of forming a catalyst on the surface of a substrate, and then causing carbon nanotube formation reaction by CVD-processing on the surface of the substrate having a catalyst to form a carbon nanotube assembly, thereby making the carbon nanotube composite according to the first and second aspects. In the carbon nanotube formation step, the temperature of the substrate is primarily increased from normal temperature to the primary target temperature T1 ranging from 400 to 600° C. before the formation of carbon nanotubes, and then the temperature is increased under control to the secondary target temperature T2 (T2≧T1) ranging from 600 to 1500° C. at a rate of 5 to 100° C./minute or maintained at the secondary target temperature T2 under introduction of a carbon source gas, thereby causing carbon nanotube formation reaction by CVD-processing on the surface of the substrate having a catalyst to grow a carbon nanotube assembly. This is advantageous for preventing agglomeration of catalysts under heating in the substrate. The high density of the carbon nanotube assembly is achieved in an as-grown state (at the time of completion of the growth of the carbon nanotube assembly) without undergoing secondary consolidation processing after the growth of the carbon nanotube assembly.

It is preferred that a ground layer of aluminum or an aluminum alloy be formed on the surface of the substrate before the formation of a catalyst on the surface of the substrate. This is advantageous for obtaining multiple carbon nanotubes oriented in the same direction.

### Advantageous Effect of the Invention

The carbon nanotube composite according to the present invention includes a carbon nanotube assembly composed of multiple carbon nanotubes which are densely formed oriented in the same direction. The carbon nanotube assembly is composed of multiple carbon nanotubes densely arranged in parallel oriented in the same direction, the carbon nanotube assembly having a high density of 70 mg/cm³ or more in a grown state (at the time of completion of the growth of the carbon nanotube assembly). Since the carbon nanotube assembly has such a high density, it has a markedly high surface area.

Furthermore, multiple carbon nanotubes are not randomly oriented, but basically oriented in the same direction, so that the carbon nanotube assembly ensures diffusibility of a fluid such as a gas along the length direction of the carbon nanotubes, high exposure of the carbon surface along the length direction of the carbon nanotubes (high utilization of the surface), high impregnating ability for substances such as an electrolyte along the length direction of the carbon nanotubes (enhancement of the function by combination), and electric and thermal conductivity along the length direction of the carbon nanotubes.

The carbon nanotube composite according to the present invention is applicable to, for example, carbon materials used in fuel cells, carbon materials used in electrodes of capacitors, lithium batteries, secondary batteries, flooded solar batteries, and electrodes of industrial instruments.

The method of the present invention allows appropriate increase of the substrate temperature through controlled temperature increase, contributes to the prevention of agglomeration of the catalyst on the surface of the substrate, stabilization of the catalyst, and stabilization of the substrate temperature before or in the early stage of carbon nanotube formation, and thus allowing the growth of carbon nanotubes with a high density.

### BRIEF DESCRIPTION OF THE DRAWINGS

FIG. 1 shows the concept of the carbon nanotube assembly formed on a substrate.

FIG. 2 is an SEM photograph showing the carbon nanotube assembly according to Example 1.

FIG. 3 is an SEM photograph showing the carbon nanotube assembly according to Example 1.

FIG. 4 is an SEM photograph showing the carbon nanotube assembly according to Example 2.

FIG. 5 is an SEM photograph showing the carbon nanotube assembly according to Example 2.

FIG. 6 is an SEM photograph showing the carbon nanotube assembly according to Example 2.

FIG. 7 is an SEM photograph showing the carbon nanotube assembly according to Example 2.

FIG. 8 is an SEM photograph showing the carbon nanotube assembly according to Example 3.

FIG. 9 is an SEM photograph showing the carbon nanotube assembly according to Example 4.

FIG. 10 is an SEM photograph showing the carbon nanotube assembly according to Example 6.

FIG. 11 is an SEM photograph showing the carbon nanotube assembly according to Example 6.

FIG. 12 is an SEM photograph showing the carbon nanotube assembly according to Example 7.

FIG. 13 is an SEM photograph showing the carbon nanotube assembly according to Example 7.

FIG. 14 is an SEM photograph showing the carbon nanotube assembly according to Example 9.

FIG. 15 shows a process of forming the carbon nanotube composite according to Application Example 1.

FIG. 16 shows a process of forming a carbon nanotube composite through the transfer of a carbon nanotube assembly according to Application Example 2.

FIG. 17 is a cross sectional view schematically showing the fuel cell according to Application Example 3.

FIG. 18 is a cross sectional view schematically showing the capacitor according to Application Example 4.

### REFERENCE NUMERALS

The reference numeral 102 represents a gas diffusion layer for anode, 103 represents a catalyst layer for anode, 104 represents a electrolyte film, 105 represents a catalyst layer for cathode, and 106 represents a gas diffusion layer for cathode.

### BEST MODE FOR CARRYING OUT THE INVENTION

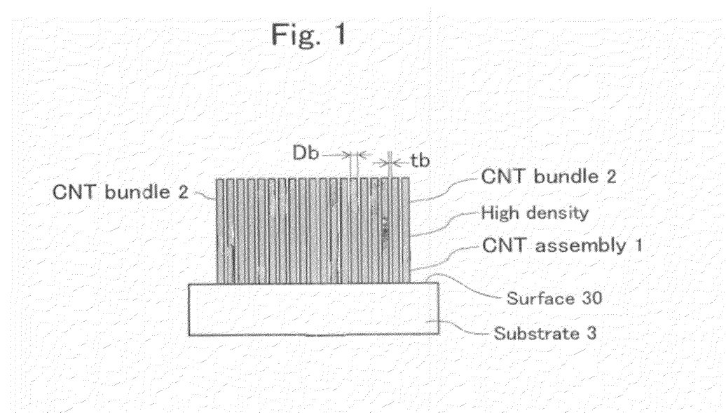

The carbon nanotube (CNT) referred herein may be a multilayer or single layer carbon nanotube. The carbon nanotube may be horn-shaped. As schematically shown in FIG. 1, a carbon nanotube assembly (1) of a carbon nanotube composite is mounted on the surface (30) of a substrate (3). The carbon nanotube assembly (1) is formed with multiple carbon nanotube bundles (2) which are vertically oriented for the flat surface (30) of the substrate (3), the carbon nanotube bundles (2) including multiple carbon nanotubes (CNT) which are vertically oriented upward from the surface (30) of the substrate (3). The density of the carbon nanotube assembly is 70 mg/cm³ or more. The length of the carbon nanotubes may be 50 μm or more.

The carbon nanotube assembly is composed of groups of multiple carbon nanotubes which are arranged in parallel with a high orientation. When the diameter of a carbon nanotube (or the diameter of a multilayer carbon nanotube, the dimension in the direction perpendicular to the extending direction of the carbon nanotube) is expressed as D, and the gap between adjacent carbon nanotubes (gap in the direction perpendicular to the extending direction of carbon nanotubes) is expressed as t, t is preferably smaller than D (D>t) with a high frequency, thereby achieving a high density of the carbon nanotube assembly. The range of D/t may be from 2 to 200, from 2 to 100, from 2 to 50, or from 2 to 10. The range will not be limited to these examples. These ranges are advantageous for achieving a high density of the carbon nanotube assembly.

In this case, as shown by the below-described examples, when the catalyst is an iron alloy such as an iron-titanium or iron-vanadium alloy, and the temperature is increased under control, the carbon nanotube assembly will have a high density of 70 mg/cm³ or more, or 90 mg/cm³ or more. The reason for this is that agglomeration of the catalyst under heating is prevented. The density is equivalent to the density of the carbon nanotube assembly in a grown state (the density when the growth of the carbon nanotube assembly is completed). The same applies to the density in the below-described examples.

As indicated in Table 1 shown below, when the catalyst is an iron alloy, and the temperature of the substrate (base plate) is appropriately increased under control in the formation of carbon nanotubes, the density of the carbon nanotube assembly may be 100 mg/cm³ or more, 120 mg/cm³ or more, or 150 mg/cm³ or more without carrying out secondary consolidation processing. Furthermore, depending on the material type of the substrate, a density of 200 mg/cm³ or more, 300 mg/cm³ or more, or 450 mg/cm³ or more can be achieved. Even furthermore, 1000 mg/cm³ or more, 1500 mg/cm³ or more, or 1800 mg/cm³ or more can be achieved. The reason for the high density of the carbon nanotubes is likely mainly due to the prevention of agglomeration of the catalyst of the substrate during heating and fine dispersion of the catalyst. In this case, after the growth of the carbon nanotube assembly, a high density of 70 mg/cm³ or more is achieved without secondary consolidation processing. Examples of the secondary consolidation processing include mechanical compression of carbon nanotubes by a mechanical external force, and exposure of carbon nanotubes to a liquid such as water followed by drying.

The substrate is preferably made of a metal or silicon. The metal composing the substrate may be at least one selected from titanium, titanium alloys, iron, iron alloys, copper, copper alloys, nickel, nickel alloys, aluminum, aluminum alloys, and silicon. Examples of the iron alloy include iron-chromium alloys, iron-nickel alloys, and iron-chromium-nickel alloys. When the substrate is a metal, its current collecting properties and electrical conductivity can be utilized.

It is preferred that a catalyst be present between the carbon nanotubes and substrate. The catalyst is normally a transition metal, and is particularly preferably a metal of V to VIII group. The catalyst is selected according to the intended density of the carbon nanotube assembly, and examples of the catalyst include iron, nickel, cobalt, molybdenum, copper, chromium, vanadium, nickel vanadium, titanium, platinum, palladium, rhodium, ruthenium, silver, gold, and alloys thereof. An alloy catalyst is likely advantageous to a single catalyst in the prevention of the agglomeration of the catalyst particles caused by heating during CVD-processing or the like, fine dispersion of the catalyst particles, and achievement of a high density of the carbon nanotube assembly. In order to achieve a high density of the carbon nanotube assembly, it is preferred that a ground layer be formed between the substrate and catalyst. It is thus preferred that the ground layer be laminated to the substrate, and then the catalyst be supported on the ground layer. The reason for this is likely that agglomeration of the catalyst particles caused by heating is prevented. The ground layer may be formed with, for example, a thin film of aluminum or an aluminum alloy. The thickness of the ground layer may be from 5 to 100 nm, or from 10 to 40 nm. In this manner, it is preferred that a catalyst be present between the carbon nanotube assembly and substrate, and a ground layer made of an aluminum or aluminum alloy be present between the catalyst and substrate.

The catalyst is preferably an A-B alloy, wherein A is preferably at least one selected from iron, cobalt, and nickel, and B is preferably at least one selected from selected from titanium, vanadium, zirconium, niobium, hafnium, and tantalum. In this case, the catalyst preferably includes at least one selected from iron-titanium alloys and iron-vanadium alloys. Other examples include cobalt-titanium alloys, cobalt-vanadium alloys, nickel-titanium alloys, nickel-vanadium alloys, iron-zirconium alloys, and iron-niobium alloys. When an iron-titanium alloy is used, the mass ratio of titanium is, for example, 5% or more, 10% or more, 20% or more, 40% or more (the balance is substantially iron), or 50% or less. When an iron-vanadium alloy is used, the mass ratio of vanadium is 5% or more, 10% or more, 20% or more, 40% or more (the balance is substantially iron), or 50% or less. An alloy catalyst is advantageous to a single metal catalyst in the prevention of agglomeration caused by heating, and the compaction of carbon nanotubes.

The method of the invention for making a carbon nanotube composite includes steps of forming a catalyst on the surface of a substrate, and then causing carbon nanotube formation reaction by CVD-processing on the surface of the substrate having a catalyst to form a carbon nanotube assembly, thereby making the carbon nanotube composite according to the first aspect. In the carbon nanotube formation step, the temperature of the substrate is primarily increased from normal temperature to the primary target temperature T1 ranging from 400 to 600° C. before the formation of carbon nanotubes, and then the temperature is increased under control to the secondary target temperature T2 ranging from 600 to 1500° C. at a rate of 5 to 100° C./minute or maintained at the secondary target temperature T2 under introduction of a carbon source gas, thereby causing carbon nanotube formation reaction by CVD-processing on the surface of the substrate having a catalyst to grow a carbon nanotube assembly. The primary target temperature T1 is preferably from 400 to 650° C., or from 400 to 600° C. at which agglomeration of catalyst particles hardly occurs on the surface of the substrate, and the formation of carbon nanotubes initiates. The secondary target temperature T2 is preferably from 600 to 1500° C., from 600 to 800° C., more than 600 to 1500° C., or more than 600 to 800° C. at which the carbon nanotubes quickly grow.

In this manner, it is preferred that carbon nanotubes be formed with the temperature of the substrate quickly increased from normal temperature to the primary target temperature T1, and slowly increased from the primary target temperature T1 to the secondary target temperature T2 during the period from the introduction of the source gas to the completion of the reaction. The reason for this is likely that agglomeration of catalyst particles caused by heating is prevented. In order to achieve a high density of the carbon nanotube assembly, it is likely preferred that the catalyst particles be finely dispersed on the substrate, and the catalyst particles be scarcely agglomerated. The secondary target temperature T2 is higher than the primary target temperature T1 (T2>T1). According to circumstances, the secondary target temperature T2 may be the same as the primary target temperature T1 (T2=T1).

Before the formation of carbon nanotubes, the temperature of the substrate is increased from normal temperature to the primary target temperature T1 (for example, 600° C., from 400 to 600° C.) at a temperature rising rate of 120 (120 to 1000)° C./minute, and then a carbon source gas (for example, a hydrocarbon gas such as acetylene or ethylene) is introduced. When the secondary target temperature T2 is, for example, from 600 to 650° C. (from 600 to 1500° C.) or more than 600 to 650° C. (more than 600 to 1500° C.), it is preferred that the temperature is increased under control from the primary target temperature T1 to the secondary target temperature T2 at a slow temperature rising rate (for example, from 3 to 5° C./minute, from 5 to 10° C./minute, from 5 to 20° C./minute, or from 5 to 30° C./minute). As a result of this, agglomeration of the catalyst scarcely occurs on the surface of the substrate, carbon nanotube formation reaction is caused by CVD-processing on the surface of the substrate having a catalyst, and a carbon nanotube assembly with a high density is grown. According to circumstances, the temperature rising rate from T1 to T2 may be from 5 to 50° C./minute, or from 5 to 100° C./minute.

According to the above-described method of the present invention, when the temperature rising rate for primarily increasing the substrate temperature from normal temperature to the primary target temperature T1 ranging from 400 to 600° C. is expressed as V1, and the temperature rising rate for secondarily increasing the substrate temperature to the secondary target temperature T2 ranging from 600 to 1500° C. (T2 T1) is expressed as V2, a relationship of V1>V2 is preferably satisfied. The reason for this is that the temperature of the substrate is quickly increased before the introduction of the source gas, thereby preventing the diffusion reaction of the catalyst before CVD-processing and the agglomeration of the catalyst on the surface of the substrate, and stabilizing the catalyst. In this manner, the temperature is slowly increased during the period from the introduction of the source gas to the completion of the reaction, thereby forming carbon nanotubes.

As described above, the reason for achieving a high density of carbon nanotubes is not clear, but likely that the controlled temperature increase is advantageous to uncontrolled temperature increase in the prevention of agglomeration of catalyst particles on the surface of the substrate, stabilization of the substrate temperature, and stabilization of the catalyst before the formation of carbon nanotubes. More specifically, agglomeration of the catalyst caused by high temperature is prevented, or variation in the activity of the catalyst caused by uneven temperature of the substrate is reduced likely by (i) the quick increase of the temperature of the substrate to the primary target temperature T1 before the introduction of the source gas of carbon nanotubes, and (ii) the slow increase of the temperature of the substrate before or in the early stage of the formation of carbon nanotubes with the substrate temperature maintained at a relatively low temperature.

In consideration of the above-described circumstances, for example, the following controlled temperature increases (a) to (d) are suggested:

(a) when the final temperature of the substrate is 600° C.,

(i) the primary target temperature T1 is 400° C., and the secondary target temperature T2 is 600° C.

(ii) the primary target temperature T1 is 500° C., and the secondary target temperature T2 is 600° C.

(iii) the primary target temperature T1 is 550° C., and the secondary target temperature T2 is 600° C.

(iv) the primary target temperature T1 is 600° C., and the secondary target temperature T2 is 600° C.;

(b) when the final temperature is 650° C.,

(i) the primary target temperature T1 is 450° C., and the secondary target temperature T2 is 650° C.

(ii) the primary target temperature T1 is 500° C., and the secondary target temperature T2 is 650° C.

(iii) the primary target temperature T1 is 550° C., and the secondary target temperature T2 is 650° C.

(iv) the primary target temperature T1 is 600° C., and the secondary target temperature T2 is 650° C.;

(c) when the final temperature is 700° C.,

(i) the primary target temperature T1 is 500° C., and the secondary target temperature T2 is 700° C.

(ii) the primary target temperature T1 is 550° C., and the secondary target temperature T2 is 700° C.

(iii) the primary target temperature T1 is 600° C., and the secondary target temperature T2 is 700° C.; and

(d) when the final temperature is 800° C.

(i) the primary target temperature T1 is 500° C., and the secondary target temperature T2 is 800° C.

(ii) the primary target temperature T1 is 550° C., and the secondary target temperature T2 is 800° C.

(iii) the primary target temperature T1 is 600° C., and the secondary target temperature T2 is 800° C.

As described above, it is preferred that the temperature of the substrate be quickly increased from normal temperature to the primary target temperature T1, thereby preventing the agglomeration of the catalyst on the surface of the substrate before CVD-processing, and the temperature be slowly increased from the primary target temperature T1 to the secondary target temperature T2 during the period from the introduction of the source gas to the completion of the reaction, thereby forming carbon nanotubes. The reason for this is likely that the agglomeration caused by heating of the catalyst particles is prevented. Accordingly, when the rate of the primary temperature increase for heating the substrate from the normal temperature to the primary target temperature T1 (400 to 600° C.) is expressed as V1, and the rate of the secondary temperature increase to the secondary target temperature T2 (600 to 1500° C.) (T2≧T1) is expressed as V2, a relationship of V1>V2 is preferably satisfied. The range of V1/V2 is, for example, from 2 to 350.

According to the present invention, the substrate is preferably made of a metal. The metal composing the substrate may be at least one selected from titanium, titanium alloys, iron, iron alloys (including stainless steel), copper, copper alloys, nickel, nickel alloys, aluminum, aluminum alloys, and silicon. The formation of a carbon nanotube assembly directly on a conductive substrate contributes to cost reduction, increase of density of carbon nanotubes, and reduction of electrical resistance at the interface between the substrate and carbon nanotube assembly. In particular, a test result indicates that a carbon nanotube assembly with a high density is formed on a substrate composed mainly of stainless steel (SUS).

The carbon nanotube composite may be used together with or independent of the substrate on which the carbon nanotube assembly had been grown. In the making method, the catalyst is preferably an A-B alloy. An alloy catalyst is likely advantageous to a single metal catalyst in the prevention of agglomeration of the catalyst on the substrate caused by heating. A is preferably at least one selected from iron, cobalt, and nickel, and B is preferably at least one selected from titanium, vanadium, zirconium, niobium, hafnium, and tantalum. In this case, the catalyst preferably includes at least one selected from iron-titanium alloys and iron-vanadium alloys. Other examples include at least one selected from cobalt-titanium alloys, cobalt-vanadium alloys, nickel-titanium alloys, nickel-vanadium alloys, iron-zirconium alloys, and iron-niobium alloys. In order to increase the density of the carbon nanotubes, the catalyst on the substrate is preferably not agglomerated. The size of the catalyst particles is, for example, from 2 to 100 nm, from 2 to 70 nm, or from 2 to 40 nm.

In the carbon nanotube formation reaction, the carbon source and process conditions are not particularly limited. Examples of the carbon source for feeding carbon for forming carbon nanotubes include aliphatic hydrocarbons such as alkane, alkene, and alkyne, aliphatic compounds such as alcohols and ethers, and aromatic compounds such as aromatic hydrocarbons. Accordingly, examples of the process include CVD method using an alcohol or hydrocarbon source gas as the carbon source (for example, CVD, plasma CVD, or remote plasma CVD method). Examples of the alcohol source gas include methyl alcohol, ethyl alcohol, propanol, butanol, pentanol, and hexanol gases. Examples of the hydrocarbon source gas include methane gas, ethane gas, acetylene gas, ethylene gas, and propane gas. The pressure in the vessel may be about 100 Pa to 0.1 MPa.

The examples of the present invention are described below.

### Example 1

### CNT/FeTi/Al/Ti, with Controlled Temperature Increase

(Base Plate)

In the present example, the catalyst was a thin film of an iron-titanium alloy. In addition, titanium was used as the base plate working as a substrate. More specifically, the base plate working as a substrate has a predetermined thickness (0.5 mm), and is made of titanium. The surface of the base plate had been polished, and the surface roughness of the base plate was 5 nm in terms of Ra.

(Pretreatment, First Layer)

As pretreatment, a ground layer of an aluminum thin film (thickness: 15 nm) as the first layer was formed by sputtering on the surface of the base plate. Sputtering was carried out using an argon gas, wherein the pressure in the reactor chamber was 0.6 Pa, and the temperature of the base plate was normal temperature (25° C.)

(Pretreatment, the Second 1 Layer)

Subsequently, as pretreatment before laminating the second layer to the first layer, the surface of the base plate was made water-repellent. The water-repellent liquid was a 5% by volume solution of hexamethylorganosilazane in toluene. The base plate having a ground layer was immersed in the water-repellent liquid in air for a predetermined time (30 minutes), subsequently, the base plate was pulled up from the water-repellent liquid, and air-dried. In the next place, in the air, the base plate was immersed in a coating liquid for 30 seconds by a dip coater. The coating liquid was prepared by dispersing iron-titanium alloy particles in hexane. The iron-titanium alloy particles had an average particle size of 5.3 nm, included 80% of iron and 20% of titanium in terms of mass ratio, the iron content being higher than the titanium content. The average particle size of the iron-titanium alloy particles was determined by TEM observation. The average particle size was simple average. The concentration of the coating liquid was adjusted such that the absorbance was 0.3 as measured by a spectrophotometer (manufactured by WPA, CO7500) at a wavelength of 680 nm. The iron-titanium alloy is likely advantageous in the increase of the density of carbon nanotubes. Thereafter, in the air and at normal temperature, the base plate was pulled up from the coating liquid at a rate of 3 mm/minute. Subsequently, after pulling up the base plate with the coating liquid adhered on the surface of the base plate, hexane was air-dried. As a result of this, a thin film of an iron-titanium alloy (thickness: 30 nm) as the second layer was formed on the ground layer of the base plate. The second layer was thicker than the ground layer. Thereafter, carbon nanotube formation was carried out.

(Carbon Nanotube Formation Method)

Carbon nanotubes were formed using a general CVD apparatus. Before the formation of carbon nanotubes, the base plate was heated to the predetermined temperature under control. A nitrogen gas as a carrier gas was introduced at a flow rate of 5000 cc/minute into the reactor chamber, which had been vacuumed to a pressure of 10 Pa, to adjust the pressure in the reactor chamber at 1×10⁵ Pa. In this state, the temperature of the base plate was quickly increased from normal temperature to 600° C. (primary target temperature T1) in 5 minutes. The temperature rising rate was 120° C./minute. As a result of this, agglomeration of the catalyst on the base plate was prevented.

The temperature was increased as described above, a mixed source gas composed of acetylene and nitrogen was fed into the reactor chamber with the temperature of the base plate increased from 600° C. to 650° C. (the secondary target temperature T2) in 6 minutes (temperature rising rate from the primary target temperature T1 to the secondary target temperature T2: 8.3° C./minute), and thus CVD-processing was carried out. In this manner, carbon nanotubes were formed with the temperature slowly increased under control during the period from the introduction of the source gas to the completion of the reaction.

The source gas was an acetylene gas and was introduced for 6 minutes at a flow rate of 500 cc/minute. As a result of this, a carbon nanotube assembly composed of multiple carbon nanotubes was formed on the iron-titanium alloy catalyst on the surface of the base plate. Many of the carbon nanotubes were multilayer carbon nanotubes. The length of the carbon nanotubes was from 140 to 150 μm, the average diameter was 9.5 nm, and the density was 130 mg/cm³. The density is equivalent to the density of the carbon nanotube assembly in a grown state (the density when the growth of the carbon nanotube assembly is completed).

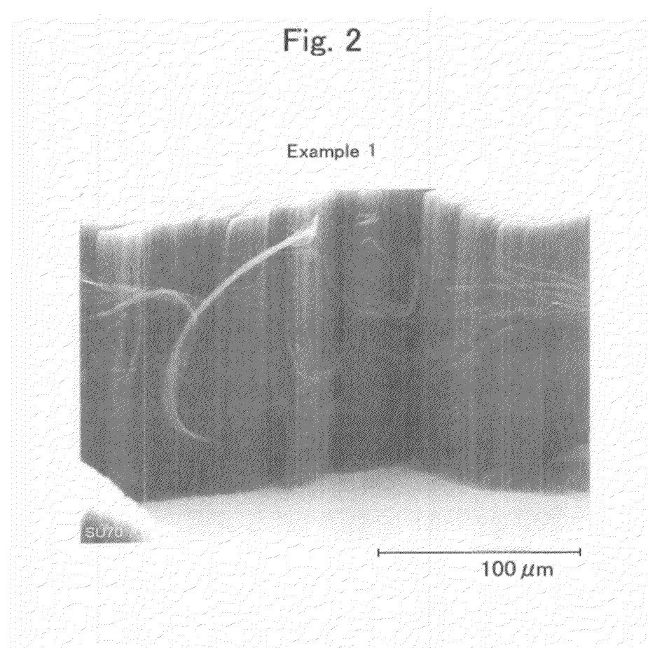

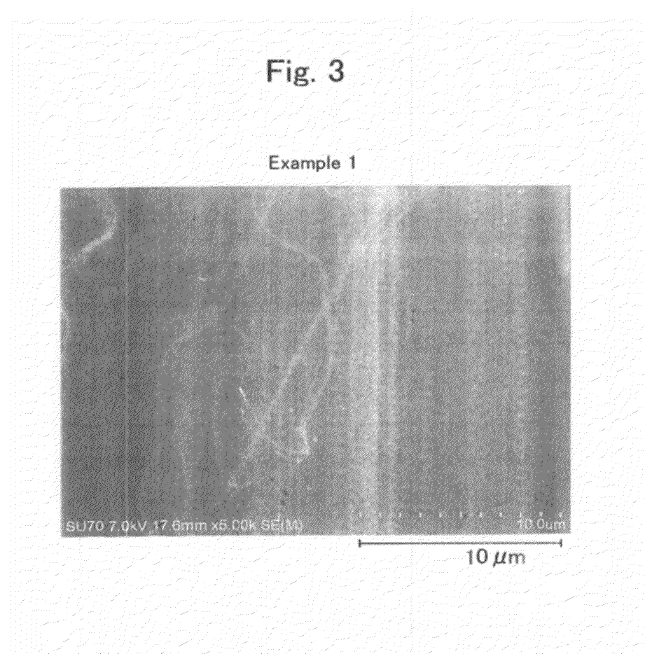

FIGS. 2 and 3 show the carbon nanotube assembly obtained. In FIG. 2, the top of the carbon nanotubes and the bottom on the base plate side are visually recognized. As understood from FIGS. 2 and 3, multiple carbon nanotube bundles are densely formed in the form of bristles on the surface of the base plate, the carbon nanotube bundles being composed of multiple carbon nanotubes vertically oriented in the same direction upward from the surface of the base plate. As understood from FIGS. 2 and 3, carbon nanotubes were oriented almost perpendicular to the surface of the base plate. The carbon nanotube bundles were also oriented almost perpendicular to the surface of the base plate. The term “carbon nanotube bundle” means a bundle of plural carbon nanotubes arranged in parallel in the direction perpendicular to the length direction of the carbon nanotubes.

As understood in FIGS. 2 and 3 showing SEM observation, a carbon nanotube assembly having a uniformly high density is formed. In addition, the carbon nanotube assembly is formed directly on the base plate, which likely contributes to the decrease of the interface resistance between the carbon nanotubes and base plate, and the decrease of electrical resistance. Furthermore, the carbon nanotube assembly has a high density and thus has many conductive paths, which likely contributes to the furthermore decrease of electrical resistance. The diameter of the carbon nanotube bundle Db was about 20 to 40 μm, the length of the carbon nanotubes was about 140 to 150 μm.

As described above, according to the present example, in the formation of carbon nanotubes, controlled temperature increase achieves a higher density of the carbon nanotube assembly in comparison with the case without controlled temperature increase. The mechanism is not clear, but likely due to the prevention of agglomeration of the catalyst on the surface of the substrate, stabilization of the temperature of the substrate, and stabilization of the catalyst. More specifically, as described above, agglomeration of the catalyst on the substrate caused by high temperature of the base plate is prevented, or variation in the activity of the catalyst caused by uneven temperature is reduced likely by (i) the quick increase of the temperature of the substrate to the primary target temperature T1 (temperature at which formation of the carbon nanotube is initiated and the agglomeration of the catalyst is prevented) before the introduction of the source gas of carbon nanotubes, and (ii) the slow increase of the temperature of the substrate from the first target temperature T1 to the second target temperature T2 in the early stage of the formation of carbon nanotubes with the substrate temperature maintained at a relatively low temperature. According to the TEM observation, one carbon nanotube had a multilayer structure including almost coaxial plural layers.

The carbon nanotube assembly including densely arranged thin carbon nanotubes had, as described above, a high density of 130 mg/cm³. The density is equivalent to the density of the carbon nanotube assembly in a grown state (the density when the growth of the carbon nanotube assembly is completed). In other words, the density was, different from Patent Document 4, achieved without secondary consolidation processing, such as exposure to water and drying, or compression of carbon nanotubes by an external force. The same applies to other examples.

The electrical resistance of the carbon nanotube assembly was 0.68 mΩ/cm² under a measurement load of 10 kgf/cm², and 0.38 mΩ/cm² under a measurement load of 40 kgf/cm². The electrical resistance of the base plate (titanium) alone having no carbon nanotube assembly was high; 58.64 mΩ/cm² under a measurement load of 10 kgf/cm², and 39.64 mΩ/cm² under a measurement load of 40 kgf/cm².

### Example 2

### CNT/FeV/Al/SUS, with Controlled Temperature Increase

(Base Plate)

In the present example, the catalyst was a thin film of an iron-vanadium alloy, and the base plate was stainless steel. More specifically, the base plate had a predetermined thickness (0.5 mm), and was made of stainless steel (JIS 304) which is an iron alloy containing chromium and nickel. The surface of the base plate had been polished, and the surface roughness was 5 nm in terms of Ra.

(Pretreatment, First Layer)

As pretreatment, a ground layer of an aluminum thin film (thickness: 15 nm) as the first layer was formed by sputtering on the surface of the base plate. In this case, an argon gas was used, the pressure in the reactor chamber was 0.6 Pa, and the temperature of the base plate was normal temperature (25° C.).

(Pretreatment, Second Layer)

Furthermore, as pretreatment, the surface of the base plate was made water-repellent. The water-repellent liquid was a 5% by volume solution of organosilazane in toluene. The base plate was immersed in the water-repellent liquid for a predetermined time (30 minutes), subsequently, the base plate was pulled up from the water-repellent liquid, and air-dried. In the next place, in the air, the base plate was immersed in a coating liquid for 30 seconds by a dip coater in the same manner as in Example 1. Subsequently, in the air and at normal temperature, the base plate was pulled up from the coating liquid at a rate of 3 mm/minute. Thereafter, after pulling up the base plate with the coating liquid adhered on the surface of the base plate, hexane on the base plate was air-dried. As a result of this, a thin film of an iron-vanadium alloy (thickness: 20 nm) as the second layer was formed on the ground layer. The second layer was thicker than the ground layer. The iron-vanadium alloy is likely advantageous for achieving a high density of the carbon nanotubes. The coating liquid was prepared by dispersing iron-vanadium alloy particles in hexane. The iron-vanadium alloy particles had an average particle size of 4.3 nm, included 85% of iron and 15% of vanadium in terms of mass ratio, the iron content being higher than the vanadium content. The concentration of the coating liquid was adjusted such that the absorbance was 0.3 as measured by a spectrophotometer (manufactured by WPA, CO7500) at a wavelength of 680 nm.

(Carbon Nanotube Formation Method)

Carbon nanotubes were formed using the CVD apparatus used in Example 1. In this case, controlled temperature increase was carried out in the same manner as in Example 1. In the controlled temperature increase, a nitrogen gas as a carrier gas was introduced at a flow rate of 5000 cc/minute into the reactor chamber which had been vacuumed to a pressure of 10 Pa, thereby adjusting the pressure in the reactor chamber at 1×10⁵ Pa. In this state, the temperature of the base plate was quickly increased from normal temperature to 600° C. in 5 minutes. The temperature rising rate was 120° C./minute. Thereafter, a mixed source gas composed of acetylene and nitrogen was fed into the reactor chamber with the temperature of the base plate increased from 600° C. to 650° C. in 6 minutes (temperature rising rate: 8.3° C./minute). In this manner, carbon nanotubes were formed with the temperature slowly increased under control during the period from the introduction of the source gas to the completion of the reaction. The source gas was an acetylene gas and was introduced for 6 minutes at a flow rate of 500 cc/minute. As a result of this, a carbon nanotube assembly composed of carbon nanotubes was formed on the iron-vanadium alloy thin film on the surface of the base plate.

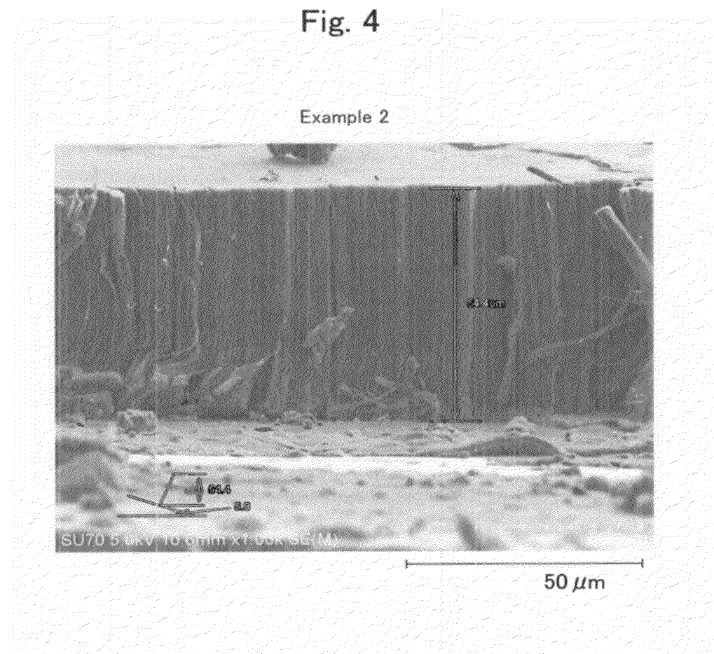

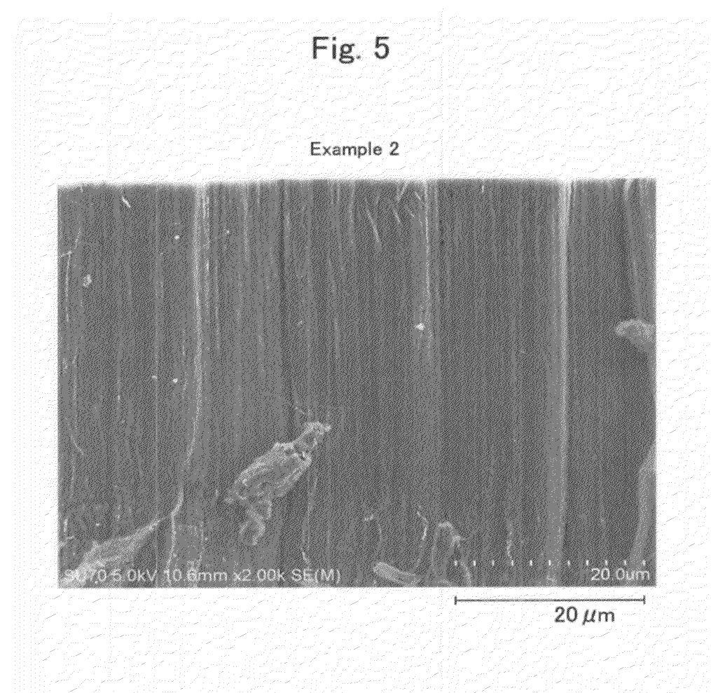

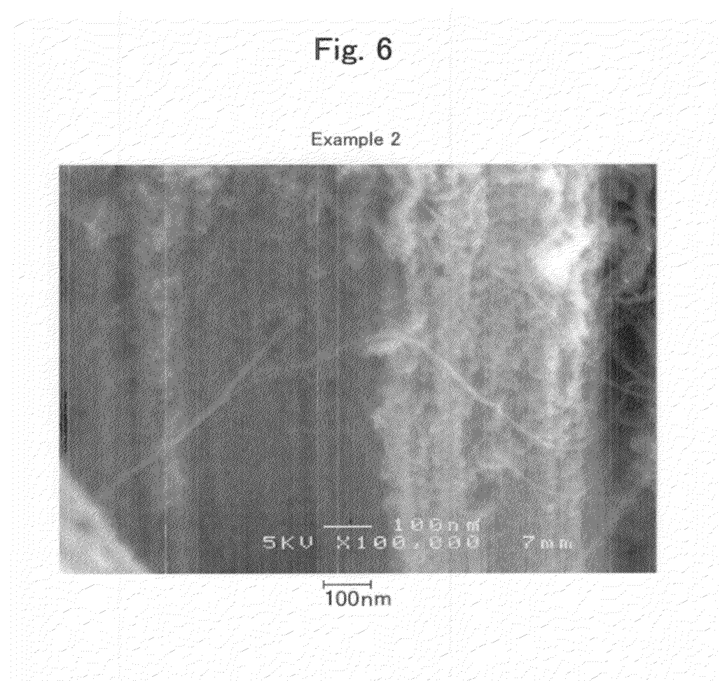

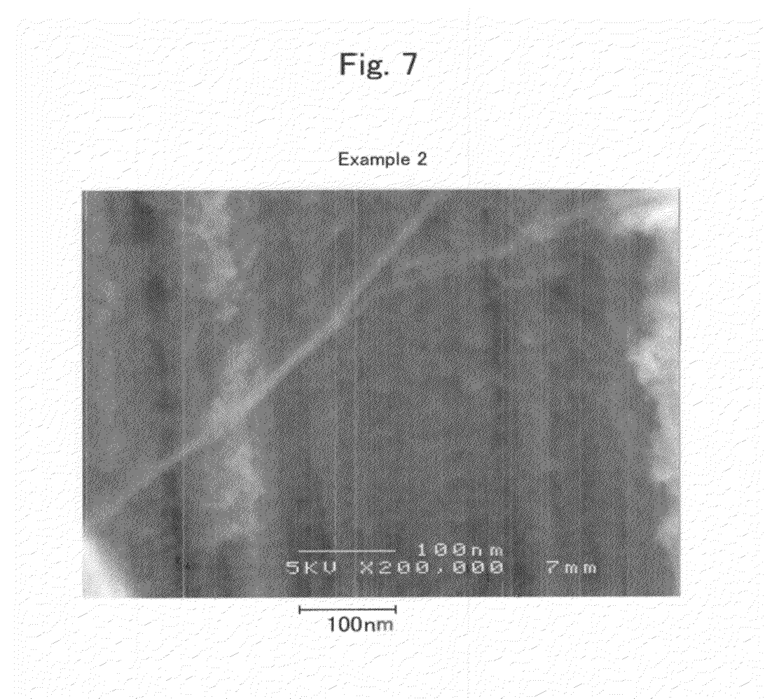

FIGS. 4 and 5 show SEM photographs according to Example 2. The carbon nanotube assembly was composed of multiple carbon nanotubes densely arranged in parallel with high vertical orientation for the base plate. The height of the carbon nanotubes was from 50 to 55 μm. According to the SEM observation, when the diameter of one carbon nanotube bundle (dimension in the direction perpendicular to the extending direction of the carbon nanotubes) is expressed as Db, the carbon nanotube bundles were adjacent in such a manner that the gap between adjacent carbon nanotube bundles (the gap in the direction perpendicular to the extending direction of the carbon nanotubes) was within Db in many regions, indicating that carbon nanotube bundles were adjacent and the carbon nanotube assembly had a high density. The probability of Db>tb was high (see FIGS. 4, 5, 6, and 7). One carbon nanotube had an average diameter of 9.0 nm, and had a multilayer structure including almost coaxial plural layers. The length of the carbon nanotubes was 50 to 55 μm, the average diameter was 9.0 nm, and the density was 520 mg/cm³. The density is equivalent to the density of the carbon nanotube assembly in a grown state (the density when the growth of the carbon nanotube assembly is completed).

When the diameter of a multilayer carbon nanotube is expressed as D, multilayer carbon nanotubes were adjacent within a dimension of D, indicating that the carbon nanotube assembly had a high density. More specifically, when the diameter of one multilayer carbon nanotube (dimension in the direction perpendicular to the extending direction of the carbon nanotubes) is expressed as D, and the gap between adjacent multilayer carbon nanotubes (the gap in the direction perpendicular to the extending direction of the carbon nanotubes) as t, t was smaller than D (D>t) in many positions with a high probability of 50% or more. The carbon nanotube assembly including a high density of thin carbon nanotubes had an extremely high density of 520 mg/cm³. The density was, different from Patent Document 4, achieved without secondary consolidation processing, such as exposure to water and drying, or compression.

### Example 3

### CNT/FeTi/Al/Cu, with Controlled Temperature Increase

(Base Plate)

In the present example, the catalyst was a thin film of an iron-titanium alloy, and the base plate was copper. More specifically, the base plate working as a substrate had a predetermined thickness (0.5 mm), and was made of copper. The surface of the base plate had been polished, and the surface roughness was 5 nm in terms of Ra.

(Pretreatment, First Layer)

As pretreatment, a ground layer of an aluminum thin film (thickness: 15 nm) as the first layer was formed by sputtering on the surface of the base plate. In this case, an argon gas was used, the pressure in the reactor chamber was 0.6 Pa, and the temperature of the base plate was normal temperature (25° C.).

(Pretreatment, Second Layer)

Furthermore, as pretreatment, the surface of the base plate was made water-repellent. In the same manner as in Example 1, the water-repellent liquid was a 5% by volume solution of organosilazane in toluene. The base plate was immersed in the water-repellent liquid for a predetermined time (30 minutes), subsequently, the base plate was pulled up from the water-repellent liquid, and air-dried. In the next place, in the air, the base plate was immersed in a coating liquid for 30 seconds by a dip coater in the same manner as in Example 1. Thereafter, in the air and at normal temperature, the base plate was pulled up from the coating liquid at a rate of 3 mm/minute. Thereafter, after pulling up the base plate with the coating liquid adhered on the surface of the base plate, hexane was air-dried. As a result of this, a thin film of an iron-titanium alloy (thickness: 30 nm) as the second layer was formed on the ground layer. The coating liquid was prepared by dispersing iron-titanium alloy particles (average particle size: 5.3 nm, 80% of iron and 20% of titanium in terms of mass ratio) in hexane. The concentration of the coating liquid was adjusted such that the absorbance was 0.3 as measured by a spectrophotometer (manufactured by WPA, CO7500) at a wavelength of 680 nm.

(Carbon Nanotube Formation Method)

Carbon nanotubes were formed using the above-described CVD apparatus. In this case, controlled temperature increase was carried out in the same manner as in Example 1. Controlled temperature increase was carried out in the same manner as in Example 1; a nitrogen gas as a carrier gas was introduced at a flow rate of 5000 cc/minute into the reactor chamber which had been vacuumed to a pressure of 10 Pa in advance, thereby adjusting the pressure in the reactor chamber to 1×10⁵ Pa. In this state, the temperature of the base plate was quickly increased from normal temperature to 600° C. in 5 minutes. The temperature rising rate was 120° C./minute in the same manner as in Example 1. Thereafter, in the same manner as in Example 1, a mixed source gas composed of acetylene and nitrogen was fed into the reactor chamber, with the temperature of the base plate increased from 600° C. to 650° C. in 6 minutes (temperature rising rate: 8.3° C./minute). In this manner, controlled temperature increase for forming carbon nanotubes was carried out with the temperature slowly increased during the period from the introduction of the source gas to the completion of the reaction. The source gas was an acetylene gas and was introduced for 6 minutes at a flow rate of 500 cc/minute. As a result of this, a carbon nanotube assembly composed of carbon nanotubes was formed on the iron-titanium alloy thin film on the surface of the base plate. The carbon nanotube assembly included multiple carbon nanotubes arranged in parallel with a high vertical orientation. When the diameter of the carbon nanotube bundle is expressed as Db, the gap tb between adjacent carbon nanotube bundles was within Db in many regions (a frequency of 50% or more of the observed points), indicating that the carbon nanotube assembly had a high density. The carbon nanotubes had an average diameter of 8.7 nm, and had a multilayer structure including almost coaxial plural layers. The density was 170 mg/cm³. The density is equivalent to the density of the carbon nanotube assembly in a grown state (the density when the growth of the carbon nanotube assembly is completed).

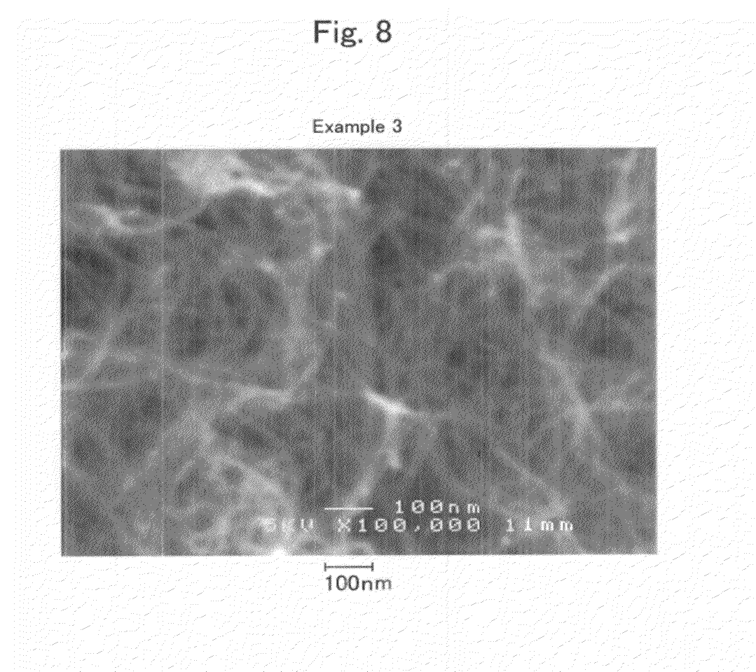

When the diameter of a carbon nanotube bundle (the dimension in the direction perpendicular to the extending direction of the carbon nanotubes) is expressed as Db, and the gap between adjacent carbon nanotube bundles (the gap in the direction perpendicular to the extending direction of carbon nanotubes) as tb, Db<tb (see FIG. 8, a frequency of 50% or more of the observed points).

The carbon nanotube assembly containing a high density of thin carbon nanotubes had a high density of 170 mg/cm³. The density was, different from Patent Document 4, achieved without secondary consolidation processing, such as exposure to water and drying, or compression by an external force. The electrical resistance of the carbon nanotube assembly was as low as 1.44 mΩ/cm² under a measurement load of 10 kgf/cm², and as low as 0.92 mΩ/cm² under a measurement load of 40 kgf/cm². The electrical resistance of the base plate (copper) alone was 0.27 mΩ/cm² under a measurement load of 10 kgf/cm², and 0.15 mΩ/cm² under a measurement load of 40 kgf/cm².

### Example 4

### CNT/FeV/Al/Cu, with Controlled Temperature Increase

(Base Plate)

In the present example, the catalyst was a thin film of an iron-vanadium alloy, and the base plate was copper. More specifically, the base plate working as a substrate had a predetermined thickness (0.5 mm), and made of copper. The surface of the base plate had been polished, and the surface roughness was 5 nm in term of Ra.

(Pretreatment, First Layer)

As pretreatment, a ground layer of an aluminum thin film (thickness: 15 nm) as the first layer was formed by sputtering on the surface of the base plate. In this case, an argon gas was used, the pressure in the reactor chamber was 0.6 Pa, and the temperature of the base plate was normal temperature (25° C.).

(Pretreatment, Second Layer)

Furthermore, as pretreatment, the surface of the base plate was made water-repellent. In the same manner as in Example 1, the water-repellent liquid was a 5% by volume solution of organosilazane in toluene. The base plate was immersed in the water-repellent liquid for a predetermined time (30 minutes), subsequently, the base plate was pulled up from the water-repellent liquid, and air-dried. In the next place, in the air, the base plate was immersed in a coating liquid for 30 seconds by a dip coater in the same manner as in Example 1. Thereafter, in the air and at normal temperature, the base plate was pulled up from the coating liquid at a rate of 3 mm/minute. Thereafter, after pulling up the base plate with the coating liquid adhered on the surface of the base plate, hexane on the base plate was air-dried. As a result of this, a thin film of an iron-vanadium alloy (thickness: 20 nm) as the second layer was formed on the ground layer. The coating liquid was prepared by dispersing iron-vanadium alloy particles (average particle size: 4.3 nm, 85% of iron and 15% of vanadium in terms of mass ratio) in hexane. The concentration of the coating liquid was adjusted such that the absorbance was 0.3 as measured by a spectrophotometer (manufactured by WPA, CO7500) at a wavelength of 680 nm.

(Carbon Nanotube Formation Method)

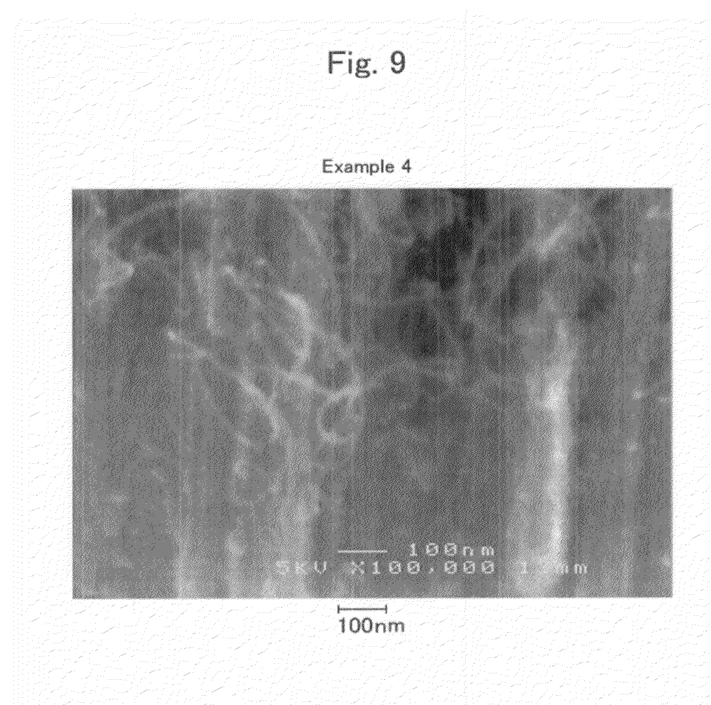

Carbon nanotubes were formed using the CVD apparatus used in Example 1. In this case, the temperature was slowly increased under control to the predetermined temperature in advance. In the controlled temperature increase, a nitrogen gas as a carrier gas was introduced at a flow rate of 5000 cc/minute into the reactor chamber which had been vacuumed to a pressure of 10 Pa to adjust the pressure in the reactor chamber to 1×10⁵ Pa. In this state, the temperature of the base plate was quickly increased from normal temperature to 600° C. in 5 minutes. In the same manner as in Example 1, the temperature rising rate was 120° C./minute. Thereafter, a mixed source gas composed of acetylene and nitrogen was fed into the reactor chamber with the temperature of the base plate increased from 600° C. to 650° C. in 6 minutes (temperature rising rate: 8.3° C./minute). In this manner, controlled temperature increase for forming carbon nanotubes was carried out with the temperature slowly increased during the period from the introduction of the source gas to the completion of the reaction. The source gas was an acetylene gas and was introduced for 6 minutes at a rate of 500 cc/minute. As a result of this, a carbon nanotube assembly composed of carbon nanotubes was formed on the iron-vanadium alloy thin film on the surface of the base plate. The carbon nanotube assembly included multiple carbon nanotubes arranged in parallel with a high vertical orientation. According to SEM observation, when the diameter of the carbon nanotube bundle is expressed as Db, carbon nanotube bundles were adjacent within a dimension of Db, and Db>tb was satisfied in multiple regions, indicating that the carbon nanotube assembly in a grown state had a high density (see FIG. 9). One carbon nanotube had an average diameter of 6.7 nm, and had a multilayer structure including almost coaxial plural layers.

When the diameter of a multilayer carbon nanotube is expressed as D, multilayer carbon nanotubes were adjacent within a dimension of D, indicating that the carbon nanotube assembly had a high density. More specifically, when the diameter of one multilayer carbon nanotube (dimension in the direction perpendicular to the extending direction of the carbon nanotubes) is expressed as D, and the gap between adjacent multilayer carbon nanotubes (the gap in the direction perpendicular to the extending direction of the carbon nanotubes) as t, t was smaller than D (D>t) in many positions with a high probability of 50% or more. The carbon nanotube assembly including a high density of thin carbon nanotubes had an extremely high density of 320 mg/cm³ (see FIG. 9). The density is equivalent to the density of the carbon nanotube assembly in a grown state (the density when the growth of the carbon nanotube assembly is completed).

### Example 5

### CNT/FeTi/Si, without Controlled Temperature Increase

(Base Plate)

In the present example, the catalyst was a thin film of an iron-titanium alloy, and the base plate was silicon. More specifically, the base plate working as a substrate had a predetermined thickness (0.5 mm), and was made of copper. The surface of the base plate had been polished, and the surface roughness was 5 nm in term of Ra.

(Pretreatment, No First Layer)

(Pretreatment, Second Layer)

Since no sputtering treatment had been carried out, as pretreatment, the surface of the base plate was made water-repellent. The water-repellent liquid was a 5% by volume solution of organosilazane in toluene. The base plate was immersed in the water-repellent liquid for a predetermined time (30 minutes), subsequently, the base plate was pulled up from the water-repellent liquid, and air-dried. In the next place, in the air, the base plate was immersed in a coating liquid for 30 seconds by a dip coater in the same manner as in Example 1. Thereafter, in the air and at normal temperature, the base plate was pulled up from the coating liquid at a rate of 3 mm/minute. Thereafter, after pulling up the base plate with the coating liquid adhered on the surface of the base plate, hexane on the base plate was air-dried. As a result of this, a thin film of an iron-titanium alloy (thickness: 30 nm) as the second layer was formed on the ground layer. The coating liquid was prepared by dispersing iron-titanium alloy particles (average particle size: 5.3 nm, 80% of iron and 20% of titanium in terms of mass ratio). The concentration of the coating liquid was adjusted such that the absorbance was 0.3 as measured by a spectrophotometer (manufactured by WPA, CO7500) at a wavelength of 680 nm.

(Carbon Nanotube Formation Method)

Carbon nanotubes were formed using the above-described CVD apparatus. In this case, controlled temperature increase was not carried out. More specifically, in the same manner as in Example 1, a nitrogen gas as a carrier gas was introduced at a flow rate of 5000 cc/minute into a reactor chamber which had been vacuumed to a pressure of 10 Pa, and the temperature of the base plate was increased from normal temperature to 600° C. in 5 minutes. The temperature rising rate was 120° C./minute. A mixed source gas composed of acetylene and nitrogen was fed into the reactor chamber with the temperature of the base plate maintained at 600° C. The source gas was an acetylene gas and was introduced for 6 minutes at a flow rate of 500 cc/minute. As a result of this, a carbon nanotube assembly composed of carbon nanotubes was formed on the iron-titanium alloy thin film on the surface of the base plate. The carbon nanotube assembly was formed with multilayer carbon nanotubes arranged in parallel in a bundle with a high vertical orientation. The carbon nanotube assembly thus formed had a high density of 80 mg/cm³. Basically, Db<tb was satisfied. This is likely due to not the controlled temperature increase but agglomeration of the catalyst.

### Example 6

### CNT/FeTi/Si, with Controlled Temperature Increase

(Base Plate)

In the present example, the catalyst was a thin film of an iron-titanium alloy, and the base plate was silicon. More specifically, the base plate working as a substrate had a predetermined thickness (0.5 mm), and was made of copper. The surface of the base plate had been polished, and the surface roughness was 5 nm in term of Ra.

(Pretreatment, No First Layer)

(Pretreatment, Second Layer)

As pretreatment, the surface of the base plate was made water-repellent. The water-repellent liquid was a 5% by volume solution of organosilazane in toluene in the same manner as in Example 1. The base plate was immersed in the water-repellent liquid for a predetermined time (30 minutes), subsequently, the base plate was pulled up from the water-repellent liquid, and air-dried. In the next place, in the air, the base plate was immersed in a coating liquid for 30 seconds by a dip coater in the same manner as in Example 1. Thereafter, in the air and at normal temperature, the base plate was pulled up from the coating liquid at a rate of 3 mm/minute. Thereafter, hexane on the base plate was air-dried with the coating liquid adhered on the surface of the base plate. As a result of this, a thin film of an iron-titanium alloy (thickness: 30 nm) as the second layer was formed on the ground layer. The coating liquid was prepared by dispersing iron-titanium alloy particles (average particle size: 5.3 nm, 80% of iron and 20% of titanium in terms of mass ratio) in hexane. The concentration of the coating liquid was adjusted such that the absorbance was 0.3 as measured by a spectrophotometer (manufactured by WPA, CO7500) at a wavelength of 680 nm.

(Carbon Nanotube Formation Method)

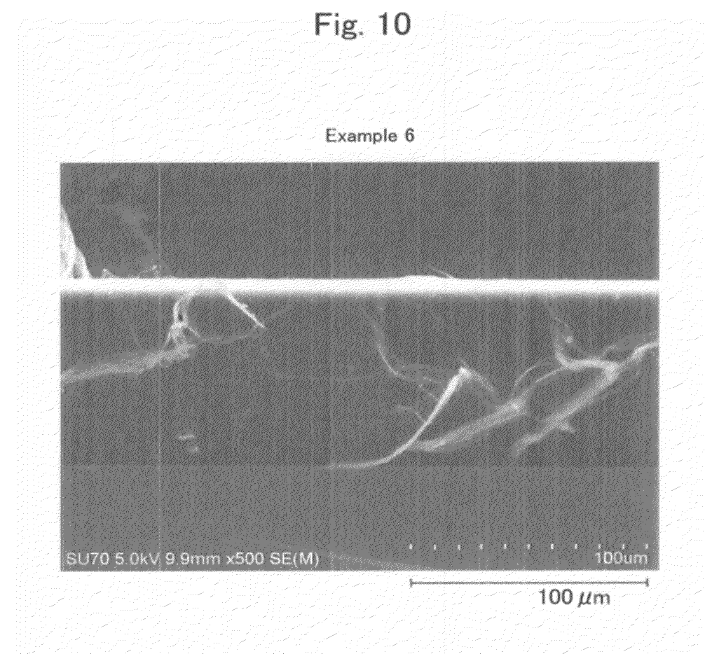

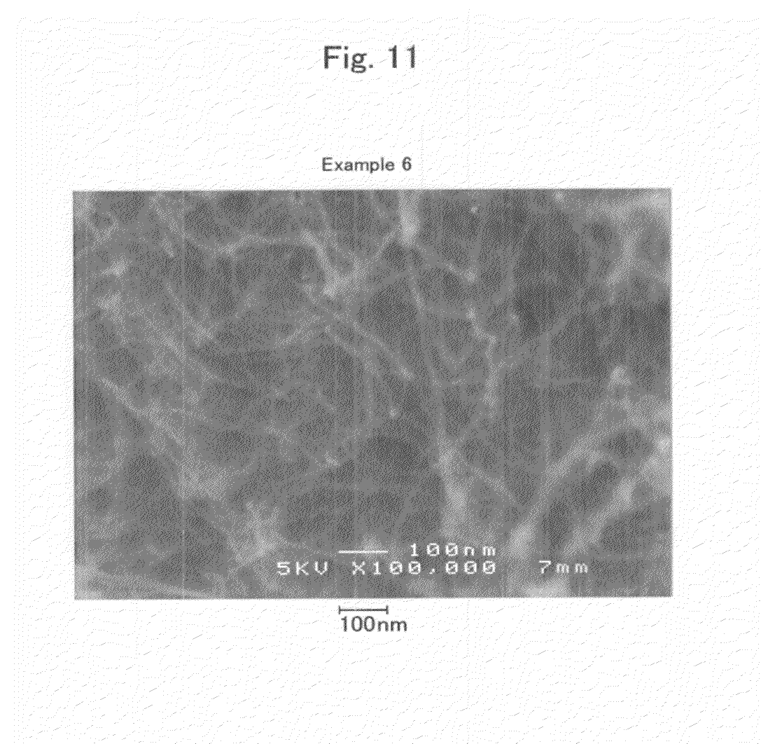

Carbon nanotubes were formed using the above-described CVD apparatus. In this case, controlled temperature increase was carried out in the same manner as in Example 1. In this case, a nitrogen gas as a carrier gas was introduced at a flow rate of 5000 cc/minute into a reactor chamber which had been vacuumed to a pressure of 10 Pa in advance, thereby adjusting the pressure in the reactor chamber to 1×10⁵ Pa. In this state, the temperature of the base plate was increased from normal temperature to 600° C. in 5 minutes. The temperature rising rate was 120° C./minute. Thereafter, a mixed source gas composed of acetylene and nitrogen was fed into the reactor chamber with the temperature of the base plate increased from 600° C. to 650° C. in 6 minutes (temperature rising rate: 8.3° C./minute). The source gas was an acetylene gas and was introduced for 6 minutes at a flow rate of 500 cc/minute. As a result of this, a carbon nanotube assembly composed of carbon nanotubes was formed on the iron-titanium alloy thin film on the surface of the base plate (see FIGS. 10 and 11). FIG. 10 shows an SEM photograph according to Example 10. As understood from FIG. 10, the carbon nanotube assembly was composed of multilayer carbon nanotubes arranged densely in parallel with a high vertical orientation for the base plate. The density of the carbon nanotube assembly thus formed had a high density of 110 mg/cm³.

### Comparative Example 1

### CNT/Fe/Al/Ti, without Controlled Temperature Increase

Comparative Example 1 was carried out basically under the same conditions as in Example 1 (base plate: titanium). In Comparative Example 1, the second layer was not an iron-titanium alloy but an iron thin film (thickness: 20 nm). An aluminum ground layer (thickness: 15 nm) was used as the first layer. In the formation of carbon nanotubes, the controlled temperature increase according to Example 1 was not carried out. More specifically, the temperature of the base plate was increased from normal temperature to 600° C. in 20 minutes. The temperature rising rate was 30° C./minute. The base plate was titanium. In Comparative Example 1, the carbon nanotube assembly had a markedly low density of 14 mg/cm³. This is likely due to the use of a single Fe catalyst, uncontrolled temperature increase, and the progress of agglomeration of the catalyst. The electrical resistance of the carbon nanotube assembly was 0.80 mΩ/cm² under a measurement load of 10 kgf/cm², and 0.48 mΩ/cm² under a measurement load of 40 kgf/cm². As understood from the comparison between Comparative Example 1 and Example 1 using a titanium base plate, the use of an iron-titanium alloy catalyst and controlled temperature increase are likely effective for achieving a high density of the carbon nanotube assembly.

### Comparative Example 2

### CNT/Fe/Al/Si, without Controlled Temperature Increase

Comparative Example 2 was carried out basically under the same conditions as in Examples 5 and 6 (base plate: silicon). In Comparative Example 2, the catalyst was not an iron-titanium alloy but an iron thin film (thickness: 20 nm). An aluminum ground layer (thickness: 15 nm) was used as the first layer. In the formation of carbon nanotubes, the controlled temperature increase according to Example 1 was not carried out. The temperature rising rate was 30° C./minute. More specifically, the temperature of the base plate was increased from normal temperature to 600° C. in 20 minutes. The base plate was silicon. The carbon nanotube assembly had a markedly low density of 13 mg/cm³. As understood from the comparison between Comparative Example 2 and Examples 5 and 6 using a silicon base plate, the use of a iron-titanium alloy thin film is likely effective for achieving a high density of the carbon nanotube assembly. Furthermore, the combination with controlled temperature increase is likely effective for achieving a higher density of the carbon nanotube assembly.

### Comparative Example 3

### Active Carbon/Conductive Adhesive/Ti, without Controlled Temperature Increase

According to Comparative Example 3, an active carbon solution was applied to the surface of the same base plate (titanium) as that used in Example 1, and dried to be hardened, thereby forming an active carbon layer. Active carbon (MT2005-2, Kureha Corporation), ketjen black, and a binder (KF Polymer #1100, Kureha Corporation) were mixed at a mass ratio of 8:1:1 to form a mixture. Subsequently, the mixture and N-methyl-2-pyrrolidone were blended at amass ratio of 3:7. The blend was kneaded for 20 minutes in an automatic mortar, dispersed for 10 minutes in an ultrasonic disperser, and thus obtaining a dispersion having a median diameter of 10 μm. The dispersion was applied to the titanium base plate using an applicator, and then dried at 130° C. for 10 minutes in the air. The electrical resistance in Comparative Example 3 was measured in the same manner as above. In this case, the electrical resistance of the active carbon layer and base plate was 54.80 mΩ/cm² under a measurement load of 10 kgf/cm², and 38.97 mΩ/cm² under a measurement load of 40 kgf/cm², indicating that they had high electrical resistance.

### Example 7

### CNT/FeTi/Al/SUS, Water Vapor Added, with Controlled Temperature Increase

(Base Plate)

In the present example, the catalyst was a thin film of an iron-titanium alloy, and the base plate was SUS304 (iron-chromium alloy, thickness 0.5 mm). The surface of the base plate had been polished, and the surface roughness was 5 nm in terms of Ra.

(Pretreatment, First Layer)

As pretreatment, a ground layer of an aluminum thin film (thickness: 15 nm) as the first layer was formed by sputtering on the surface of the base plate. In this case, an argon gas was used, the pressure in the reactor chamber was 0.6 Pa, and the temperature of the base plate was normal temperature (25° C.).

(Pretreatment, Second Layer)

Furthermore, as pretreatment, the surface of the base plate was made water-repellent. In the same manner as in Example 1, the water-repellent liquid was a 5% by volume solution of organosilazane in toluene. The base plate was immersed in the water-repellent liquid for a predetermined time (30 minutes), subsequently, the base plate was pulled up from the water-repellent liquid, and air-dried. In the next place, in the air, the base plate was immersed in a coating liquid for 30 seconds by a dip coater in the same manner as in Example 1. Thereafter, in the air and at normal temperature, the base plate was pulled up from the coating liquid at a rate of 3 mm/minute. Thereafter, after pulling up the base plate with the coating liquid adhered on the surface of the base plate, hexane on the base plate was air-dried. As a result of this, a thin film of an iron-titanium alloy (thickness: 30 nm) as the second layer was formed on the ground layer. The coating liquid was prepared by dispersing iron-titanium alloy particles (average particle size: 5.3 nm, 80% of iron and 20% of titanium in terms of mass ratio) in hexane. The concentration of the coating liquid was adjusted such that the absorbance was 0.3 as measured by a spectrophotometer (manufactured by WPA, CO7500) at a wavelength of 680 nm.

(Carbon Nanotube Formation Method)

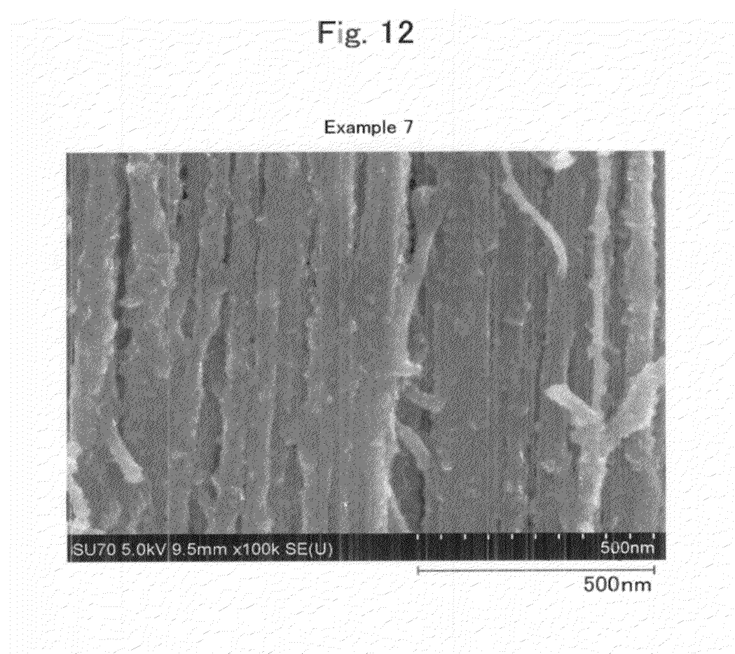

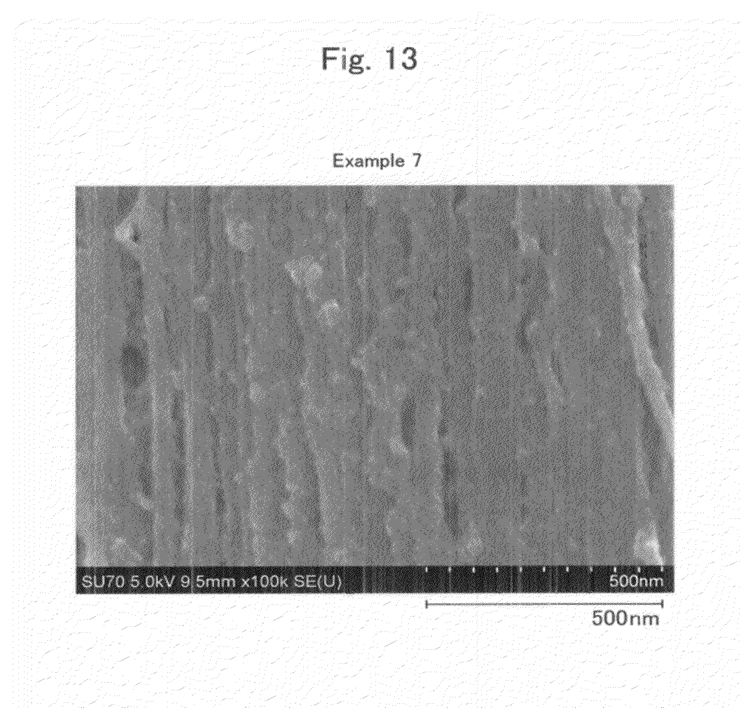

Carbon nanotubes were formed using the CVD apparatus used in Example 1. In this case, the temperature was slowly increased under control to the predetermined temperature in advance. In the controlled temperature increase, a nitrogen gas as a carrier gas was introduced at a flow rate of 5000 cc/minute into a reactor chamber which had been vacuumed to a pressure of 10 Pa, thereby adjusting the pressure in the reactor chamber to 1×10⁵ Pa. In this state, the temperature of the base plate was quickly increased from normal temperature to 700° C. in 5 minutes. The temperature rising rate was 190° C./minute, which was higher than in Example 1. After the temperature was increased to 700° C., the temperature of the base plate was slowly increased (temperature rising rate: 5° C./minute) from 700° C. to 730° C. in 6 minutes under introduction of a nitrogen gas and a mixed source gas composed of 500 cc/minute of an acetylene gas as a carbon source and 1 cc/minute of water vapor into the reactor chamber for 6 minutes. As a result of this, a carbon nanotube assembly composed of carbon nanotubes (see FIGS. 12 and 13) was formed on the iron-titanium alloy thin film on the surface of the base plate. The carbon nanotube assembly included multiple carbon nanotubes arranged in parallel with a high vertical orientation. According to SEM observation, when the diameter of the carbon nanotube bundle is expressed as Db, the carbon nanotube bundles were adjacent within a dimension of Db, indicating that the carbon nanotube assembly had a high density (a frequency of 60% or more of the observed points). The length of one carbon nanotube was from 10 to 30 μm, and the average diameter was 25 nm.

When the diameter of one multilayer carbon nanotube is expressed as D, the multilayer carbon nanotubes were adjacent within a dimension of D, and D>t was satisfied in many regions (see FIGS. 12 and 13, a frequency of 60% or more of the observed points). In this manner, the carbon nanotubes were dense and had a high density. More specifically, when the diameter of one multilayer carbon nanotube (the dimension in the direction perpendicular to the extending direction of the carbon nanotube) is expressed as D, and the gap between adjacent multilayer carbon nanotubes (the gap in the direction perpendicular to the extending direction of the carbon nanotubes) as t, t was smaller than D in many regions with a high probability of 50% or more (D>t, see FIGS. 12 and 13). The carbon nanotube assembly including a high density of thin carbon nanotubes had a extremely high density of 1720 mg/cm³.

According to the present example, the main reason for the addition of water vapor to the source gas is as follows. More specifically, if amorphous carbon is formed near the seed catalyst on the base plate during CVD-processing, the reaction for forming carbon nanotubes is limited, and the growth of carbon nanotubes may be hindered. Therefore, water vapor (H₂O) is added to the source gas, and a rather oxidizing atmosphere containing oxygen is formed, thereby oxidizing and eliminating the amorphous carbon limiting the formation of carbon nanotubes. At the same time, oxidation of the catalyst occurs, the activity of catalysts is equalized, so that the catalysts forming no carbon nanotube decrease, which likely results in the formation of dense carbon nanotubes.

### Example 8

### CNT/FeTi/Al/SUS, Water Vapor+Hydrogen Added, with Controlled Temperature Increase

(Base Plate)

In the present example, the catalyst was a thin film of an iron-titanium alloy, and the base plate was SUS304 (iron-chromium alloy, thickness 0.5 mm). The surface of the base plate had been polished, and the surface roughness was 5 nm in term of Ra.

(Pretreatment, First Layer)

As pretreatment, a ground layer of an aluminum thin film (thickness: 15 nm) as the first layer was formed by sputtering on the surface of the base plate. In this case, an argon gas was used, the pressure in the reactor chamber was 0.6 Pa, and the temperature of the base plate was normal temperature (25° C.).

(Pretreatment, Second Layer)

Furthermore, as pretreatment, the surface of the base plate was made water-repellent. In the same manner as in Example 1, the water-repellent liquid was a 5% by volume solution of organosilazane in toluene. The base plate was immersed in the water-repellent liquid for a predetermined time (30 minutes), subsequently, the base plate was pulled up from the water-repellent liquid at a rate of 3 mm/minute, and air-dried. In the next place, in the air, the base plate was immersed in a coating liquid for 30 seconds by a dip coater in the same manner as in Example 1. Thereafter, in the air and at normal temperature, the base plate was pulled up from the coating liquid at a rate of 3 mm/minute. After pulling up the base plate with the coating liquid adhered on the surface of the base plate, hexane on the base plate was air-dried. As a result of this, a thin film of an iron-titanium alloy (thickness: 30 nm) as the second layer was formed on the ground layer. The coating liquid was prepared by dispersing iron-titanium alloy particles (average particle size: 5.3 nm, 80% of iron and 20% of titanium in terms of mass ratio) in hexane. The concentration of the coating liquid was adjusted such that the absorbance was 0.3 as measured by a spectrophotometer (manufactured by WPA, CO7500) at a wavelength of 680 nm.

(Carbon Nanotube Formation Method)

Carbon nanotubes were formed using the CVD apparatus used in Example 1. In this case, the temperature was slowly increased under control to the predetermined temperature in advance. In the controlled temperature increase, a mixed gas composed of 2000 cc/minute of a nitrogen gas and 3000 cc/minute of a hydrogen gas as a carrier gas was introduced into a reactor chamber which had been vacuumed to a pressure of 10 Pa, thereby adjusting the pressure in the reactor chamber to 1×10⁵ Pa. In this state, the temperature of the base plate was quickly increased from normal temperature to 700° C. in 5 minutes. The temperature rising rate was 140° C./minute, which was higher than in Example 1. After the temperature was increased to 700° C., the temperature of the base plate was slowly increased (temperature rising rate: 5° C./minute) from 700° C. to 730° C. in 6 minutes under introduction of the carrier gas and a mixed source gas composed of 500 cc/minute of an acetylene gas as a carbon source and 1 cc/minute of water vapor into the reactor chamber for 6 minutes. As a result of this, a carbon nanotube assembly composed of carbon nanotubes was formed on the iron-titanium alloy catalyst on the surface of the base plate. The carbon nanotube assembly included multiple carbon nanotubes arranged in parallel with a high vertical orientation. According to SEM observation, when the diameter of the carbon nanotube bundle is expressed as Db, the carbon nanotube bundles were adjacent within a dimension of Db, indicating that the carbon nanotube assembly had a high density (a frequency of 50% or more of the observed points). One carbon nanotube had a markedly long length of 200 to 250 μm, and an average diameter of 11 nm.

When the diameter of one multilayer carbon nanotube is expressed as D, in the same manner as in Example 7, the multilayer carbon nanotubes were adjacent within a dimension of D, and D>t was satisfied in many regions with a high frequency (a frequency of 50% or more of the observed points). In this manner, the carbon nanotube assembly had a high density. The carbon nanotube assembly including a high density of thin carbon nanotubes had a high density of 220 mg/cm³.

According to the present example, the source gas contains water vapor and a hydrogen gas, thereby serving as an oxidizing atmosphere and a reducing atmosphere. An oxide film may be formed on the catalyst on the base plate, so that the removal of the oxide film by the reducing atmosphere created by hydrogen gas increase the activity of the catalyst, and promotes the growth of the carbon nanotubes. The reason for the use of water vapor is the same as that in Example 7.

### Example 9

### CNT/FeTi/Al/SUS, Water Vapor+Hydrogen Added+Long Time CVD-Processing, with Controlled Temperature Increase

(Base Plate)

In the present example, the catalyst was a thin film of an iron-titanium alloy, and the base plate was SUS304 (iron-chromium alloy, thickness 0.5 mm). The surface of the base plate had been polished, and the surface roughness was 5 nm in term of Ra.

(Pretreatment, First Layer)

As pretreatment, a ground layer of an aluminum thin film (thickness: 15 nm) as the first layer was formed by sputtering on the surface of the base plate. In this case, an argon gas was used, the pressure in the reactor chamber was 0.6 Pa, and the temperature of the base plate was normal temperature (25° C.).

(Pretreatment, Second Layer)

Furthermore, as pretreatment, the surface of the base plate was made water-repellent. In the same manner as in Example 1, the water-repellent liquid was a 5% by volume solution of organosilazane in toluene. The base plate was immersed in the water-repellent liquid for a predetermined time (30 minutes), subsequently, the base plate was pulled up from the water-repellent liquid, and air-dried. In the next place, in the air, the base plate was immersed in a coating liquid for 30 minutes by a dip coater in the same manner as in Example 1. Thereafter, in the air and at normal temperature, the base plate was pulled up from the coating liquid at a rate of 3 mm/minute. Hexane on the base plate was air-dried with the coating liquid adhered on the surface of the base plate. As a result of this, a thin film of an iron-titanium alloy (thickness: 30 nm) as the second layer was formed on the ground layer. The coating liquid was prepared by dispersing iron-titanium alloy particles (average particle size: 5.3 nm, 80% of iron and 20% of titanium in terms of mass ratio) in hexane. The concentration of the coating liquid was adjusted such that the absorbance was 0.3 as measured by a spectrophotometer (manufactured by WPA, CO7500) at a wavelength of 680 nm.

(Carbon Nanotube Formation Method)

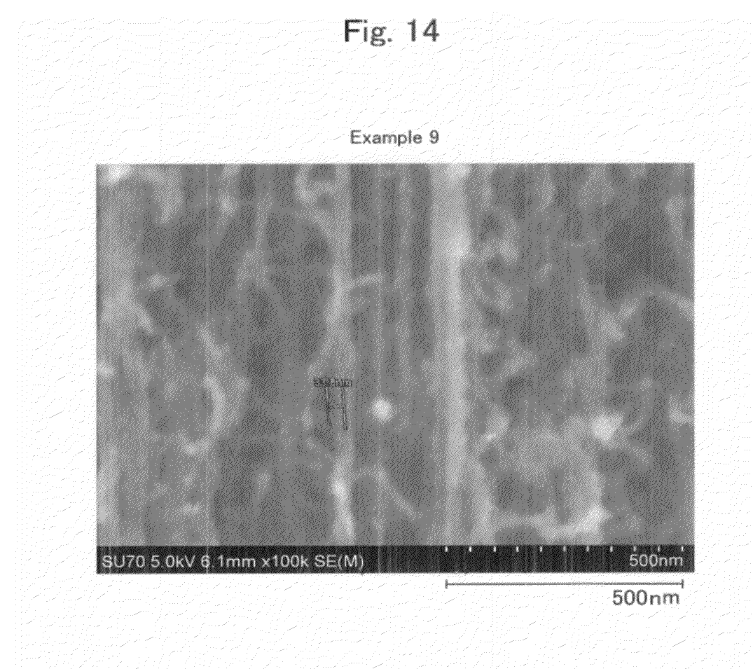

Carbon nanotubes were formed using the CVD apparatus used in Example 1. In this case, the temperature was slowly increased under control to the predetermined temperature. In the controlled temperature increase, a mixed gas composed of 2000 cc/minute of a nitrogen gas and 3000 cc/minute of a hydrogen gas as a carrier gas was introduced into a reactor chamber which had been vacuumed to a pressure of 10 Pa in advance, thereby adjusting the pressure in the reactor chamber to 1×10⁵ Pa. In this state, the temperature of the base plate was quickly increased from normal temperature to 700° C. in 5 minutes. The temperature rising rate was 140° C./minute, which was higher than in Example 1. After the temperature was increased to 700° C., the temperature of the base plate was slowly increased (temperature rising rate: 1° C./minute) from 700° C. to 730° C. in 30 minutes under introduction of the carrier gas and a mixed source gas composed of 500 cc/minute of an acetylene gas as a carbon source and 1 cc/minute of water vapor into the reactor chamber. As a result of this, a carbon nanotube assembly composed of carbon nanotubes was formed on the iron-titanium alloy thin film on the surface of the base plate. The carbon nanotube assembly included multiple carbon nanotubes arranged in parallel with a high vertical orientation (FIG. 14).

According to SEM observation, when the diameter of the carbon nanotube bundle is expressed as Db, in the same manner as in Example 7, the carbon nanotube bundles were adjacent within a dimension of Db, indicating that the carbon nanotube assembly had a high density (a frequency of 60% or more of the observed points). The length of one carbon nanotube was markedly long (310 to 350 μm).

When the diameter of one multilayer carbon nanotube is expressed as D, the multilayer carbon nanotubes were adjacent within a dimension of D, and D>t was satisfied in many regions (FIG. 14, a frequency of 60% or more of the observed points). In this manner, the carbon nanotube assembly had a high density. The carbon nanotube assembly including a high density of thin carbon nanotubes had a high density of 480 mg/cm³. The basis weight of the carbon nanotubes was 16 mg/cm². According to the present example, the introduction of the source gas for a long time (30 minutes) is intended to increase the length and surface area of the carbon nanotubes.

[Measurement Method of Density of Carbon Nanotube Assembly]

The density of the carbon nanotube assembly was determined as follows. More specifically, the weight W [g] of the carbon nanotube assembly itself was measured by measuring the weight before and after the formation of the carbon nanotube assembly on the surface of the base plate. The W [g] was divided by the area S on the base plate on which the carbon nanotube assembly was formed. In this manner, the basis weight W/S [g/cm²] of the carbon nanotubes per unit area was calculated. Furthermore, the cross section of the carbon nanotube assembly was observed by SEM, and the film thickness [μm] of the carbon nanotube assembly was measured. In consideration of the film thickness, the density of the carbon nanotube assembly [g/cm³] was calculated.

[Measurement Method of Electrical Resistance of Carbon Nanotube Assembly]

Firstly, the electrical resistance on the surface of the base plate along the normal direction was measured by direct current two-terminal method, and recorded as the electrical resistance of the base plate. In this case, measuring electrodes were made of stainless steel plated with gold. The sample was a carbon nanotube assembly formed on the substrate, and the carbon nanotube assembly was sandwiched by the two measuring electrodes together with the base plate in the thickness direction of the base plate. In this case, the measurement area was 1 cm², and the measurement current was 3 A. The voltage value [V] under a measurement load (10 kgf/cm²) was measured, and the electrical resistance [mΩ·cm²] was calculated. In addition, the voltage value [V] under a measurement load (40 kgf/cm²) was measured, and the electrical resistance [mΩ·cm²] of entire laminate of the carbon nanotubes/the substrate in the normal direction was calculated.

[Explanation of Tables]

Tables 1 to 3 show the results of examples and test examples carried out by the inventors. The material of the base plate forming the carbon nanotube assembly was titanium, stainless steel (SUS), copper, or silicon. Table 1 shows the density of carbon nanotube assemblies. In Table 1, the symbol ◯ means a high density and good, ⊚ means a high density and very good. As understood from Table 1, when an appropriate catalyst was used and controlled temperature increase was carried out, the carbon nanotube assembly had a high density of 70 mg/cm³ or more irrespective of whether the material of the base plate was titanium, stainless steel (SUS), copper, or silicon.

Table 2 shows the electrical resistance of the carbon nanotube assembly (electrical resistance of the base plate and carbon nanotube assembly) under a measurement load of 10 kgf/cm². Table 3 shows the electrical resistance of the carbon nanotube assembly (electrical resistance of the base plate and carbon nanotube assembly) under a measurement load of 40 kgf/cm². Tables 2 and 3 also show the electrical resistance of the base plate alone and the electrical resistance of an active carbon layer laminated to the base plate. As understood from Tables 2 and 3, the electrical resistance of the carbon nanotube assembly was relatively low.

As understood from Tables 2 and 3, the electrical resistance of the base plate (titanium) alone having no carbon nanotube assembly was high; 58.64 mΩ/cm² under a measurement load of 10 kgf/cm², and 39.64 mΩ/cm² under a measurement load of 40 kgf/cm². The electrical resistance of the base plate (stainless steel) alone which had no carbon nanotube assembly was 82.28 mΩ/cm² under a measurement load of 10 kgf/cm², and 38.45 mΩ/cm² under a measurement load of 40 kgf/cm², indicating it had high electrical resistance. The electrical resistance of the base plate (copper) alone having no carbon nanotube assembly was 0.27 mΩ/cm² under a measurement load of 10 kgf/cm², and 0.15 mΩ/cm² under a measurement load of 40 kgf/cm². In particular, when the base plate was made of stainless steel or titanium, the electrical resistance of the base plate having the carbon nanotubes was markedly lower than that of the base plate alone. These base plates tend to have a passivation film (insulative oxide film) on their surfaces, and thus have very high electrical resistance. However, the resistance of the entire laminate was markedly reduced likely by (i) the removal of the oxide film in a reducing atmosphere during CVD-processing, and (ii) the reduction of interface resistance between the carbon nanotubes and base plate due to the formation of carbon nanotubes directly on the base plate.

TABLE 1
Density of CNT assembly mg/cm³

| | Ti | SUS | Cu | Si |
|---|---|---|---|---|
| Active carbon coating/base plate | 20 | — | — | — |
| CNT/base plate (catalyst: Fe) | 14 | — | — | 13 |
| High-density CNT/base plate | — | — | — | 80 ◯ |
| (catalyst: Fe—Ti) | | | | |
| High-density CNT/base plate | 130 ◯ | — | 170 ◯ | 110 ◯ |
| (catalyst: Fe—Ti), with | | | | |
| controlled temperature increase | | | | |
| High-density CNT/base plate | — | 520 ⊚ | 320 ⊚ | — |
| (catalyst: Fe—V), with | | | | |
| controlled temperature increase | | | | |

Density evaluation
◯: good,
⊚: very good

TABLE 2
Measurement load: 10 kgf/cm²
Resistance of CNT assembly mΩ · cm²

| | Ti | SUS | Cu | Si |
|---|---|---|---|---|
| Base plate alone | 58.64 | 82.28 | 0.27 | — |
| Active carbon coating/base plate | 54.80 | 41.62 | — | — |
| CNT/base plate (catalyst: Fe) | 0.80 | 5.76 | — | — |
| High-density CNT/base plate | — | — | — | — |
| (catalyst: Fe—Ti) | | | | |
| High-density CNT/base plate | 0.68 | 3.68 | 1.44 | — |
| (catalyst: Fe—Ti), with | | | | |
| controlled temperature increase | | | | |
| High-density CNT/base plate | — | — | — | — |
| (catalyst: Fe—V), with | | | | |
| controlled temperature increase | | | | |

TABLE 3
Measurement load: 40 kgf/cm²
Resistance of CNT assembly mΩ · cm²

| | Ti | SUS | Cu | Si |
|---|---|---|---|---|
| Base plate alone | 39.64 | 38.45 | 0.15 | — |
| Active carbon coating/base plate | 38.97 | 18.63 | — | — |
| CNT/base plate (catalyst: Fe) | 0.48 | 2.41 | — | — |
| High-density CNT/base plate | — | — | — | — |
| (catalyst: Fe—Ti) | | | | |
| High-density CNT/base plate | 0.38 | 1.45 | 0.92 | — |
| (catalyst: Fe—Ti), with | | | | |
| controlled temperature increase | | | | |
| High-density CNT/base plate | — | — | — | — |
| (catalyst: Fe—V), with | | | | |
| controlled temperature increase | | | | |

### Application Example 1

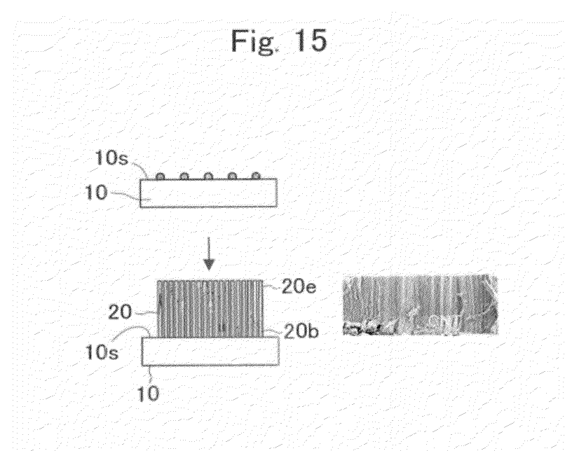

FIG. 15 shows Application Example 1. According to the present example, in the same manner as in the examples, a carbon nanotube assembly 20 including multiple carbon nanotubes on a surface 10s of the base plate 10 oriented in the vertical direction. As shown in FIG. 15, the base 20b of carbon nanotubes is held on the surface 10s of the base plate 10 composed mainly of at least one metal selected from Cu, Al, SUS, and Ti which serves as a conductive collector. The carbon nanotubes extend from the base 20b to the tip 20e, oriented perpendicular to the surface 10s of the base plate 10. The carbon nanotube assembly 20 is dense and has a high density and a high surface area. In addition, the carbon nanotube assembly 20 is formed directly on the surface 10s of the base plate 10 composed mainly of at least one metal selected from Cu, Al, SUS, and Ti which serves as a conductive collector. Therefore, the interface resistance between the carbon nanotubes and collector is low.

### Application Example 2

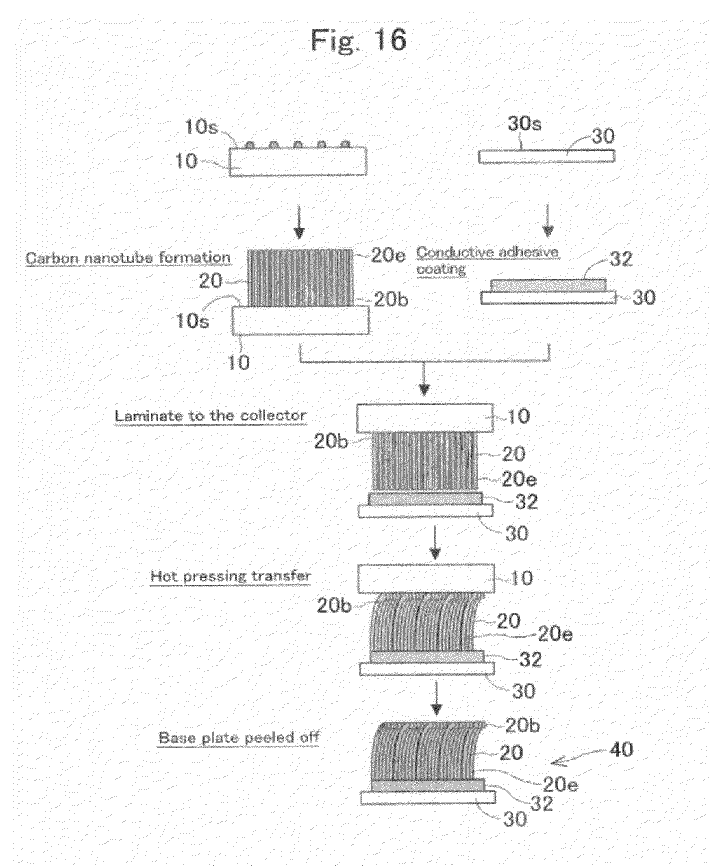

FIG. 16 shows Application Example 2. According to the present example, in the same manner as in the examples, a carbon nanotube assembly 20 is formed on the surface 10s of a base plate 10 as a substrate. As shown in FIG. 16, the base 20b of carbon nanotubes is held on the surface 10s of the base plate 10. The carbon nanotubes extend from the base 20b to the tip 20e, oriented perpendicular to the surface 10s of the base plate 10. Furthermore, an adhesive layer 32 coated with a conductive adhesive is laminated to the surface 30s of a collector 30 which serves as a transfer substrate (the adhesive may be not applied according to circumstances). Subsequently, the tip 20e of the carbon nanotube assembly 20 on the base plate 10 is pressed against the adhesive layer 32 of the collector 30, and the base plate 10, carbon nanotube assembly 20, and collector 30 are stacked in this order to form a laminate. Subsequently, the laminate is compressed in the thickness direction of the base plate 10 under heating, thereby carrying out hot pressing transfer. As a result of this, the tip 20e of the carbon nanotube assembly 20 is transferred to the adhesive layer 32 of the collector 30. Subsequently, the base plate 10 is peeled off from the base 20b of the carbon nanotube assembly 20. As a result of this, a carbon nanotube composite 40 including the carbon nanotube assembly 20 mounted on the collector 30 (transfer substrate) is formed. In the carbon nanotube composite 40, the carbon nanotubes are densely arranged with a high density, and have a large specific surface area.

### Application Example 3

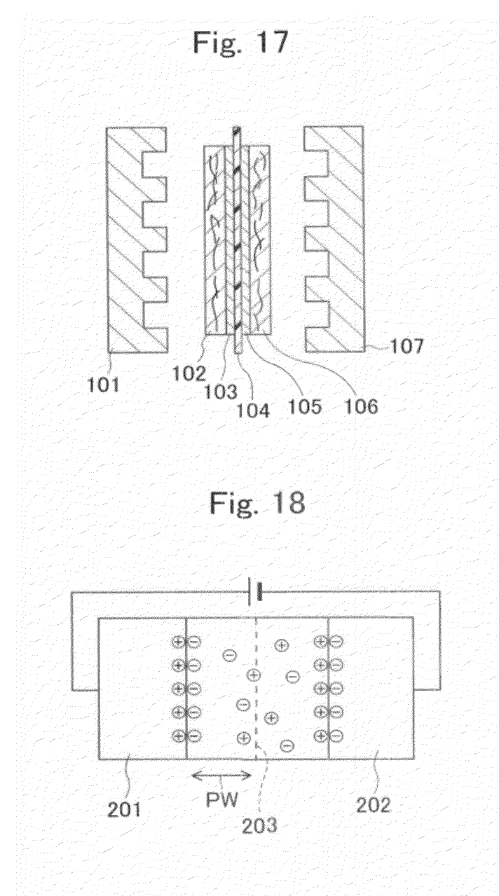

FIG. 17 schematically shows a cross section of the essential part of a sheet-shaped polymer fuel cell. The fuel cell includes a distributing plate 101 for anode, a gas diffusion layer 102 for anode, a catalyst layer 103 having a catalyst for anode, an electrolyte film 104 with ion conductivity (proton conductivity) made of a fluorocarbon or hydrocarbon polymer material, a catalyst layer 105 having a catalyst for cathode, a gas diffusion layer 106 for cathode, and a distributing plate 107 for cathode, these components being laminated in this order in the thickness direction. The gas diffusion layers 102 and 106 have gas permeability for passing the reaction gas. The electrolyte film 104 may be made of a glass having ionic conductivity.

The carbon nanotube composite according to the present invention may be used in the gas diffusion layer 102 and/or the gas diffusion layer 106. In this case, the carbon nanotube composite according to the present invention is porous and has a large specific surface area, and thus is expected to achieve the increase of gas permeability, prevention of flooding, reduction of electrical resistance, and improvement of electrical conductivity. Flooding is a phenomenon wherein the channel resistance of the reaction gas channel is blocked and decreased by the water of the liquid phase, and thus passage of the reaction gas decreases.

According to circumstances, the carbon nanotube composite according to the present invention may support a catalyst such as platinum in the catalyst layer 103 for anode and/or the catalyst layer 105 for cathode. In this case, the carbon nanotube composite according to the present invention has a large specific surface area due to its high density, and has a high catalyst supporting efficiency due to its porosity. Accordingly, adjustments of discharge of generated water and permeability of the reaction gas are expected, and thus the carbon nanotube composite is advantageous for preventing flooding. Furthermore, improvement in utilization of catalyst particles such as platinum particles, ruthenium particles, or platinum-ruthenium particles is expected.

According to another circumstance, a carbon nanotube composite allows integration of an electrode structure having both functions of a gas diffusion layer and a catalyst layer. An integral electrode including a carbon nanotube composite, platinum, an ionomer, and as necessary a water repellent achieves the above-described effect due to the application to the respective members, and allows the reduction of interface resistance between the diffusion layer and catalyst layer, and cost reduction of the electrode process. The fuel cell may be sheet-shaped or tube-shaped.

### Application Example 4

FIG. 18 schematically shows a collecting capacitor. The capacitor includes a porous positive electrode 201 composed mainly of a carbon material formed with the carbon nanotube composite according to the present invention, a porous negative electrode 202 composed mainly of a carbon material formed with the carbon nanotube composite according to the present invention, and a separator 203 separating the positive electrode 201 from the negative electrode 202. The carbon nanotube composite according to the present invention is porous and has a high density and a large specific surface area. Therefore, the carbon nanotube composite used in the positive electrode 201 and/or the negative electrode 202 is expected to increase the current collection volume, and improve the ability of the capacitor. It is preferred that the carbon nanotubes be oriented in such a manner that the carbon nanotubes extends in the length direction along the virtual line PW connecting the negative electrode 202 and the positive electrode 201. In this case, the electrolytic solution contained in the capacitor readily flows along the length direction of the carbon nanotubes. It is thus expected that the positive and negative ions readily move along the carbon nanotubes. Since the carbon nanotube assembly has a high density, the capacitor has a high output density (low resistance) and a high volume density (high surface area).

### Other Examples

According to the above-described examples, the catalyst is an iron-titanium alloy or an iron-vanadium alloy. Alternatively, the catalyst may be a cobalt-titanium alloy, a cobalt-vanadium alloy, a nickel-titanium alloy, a nickel-vanadium alloy, an iron-zirconium alloy, or an iron-niobium alloy. The present invention will not be limited to the above-described embodiments, examples, and application examples, but may be modified as appropriate without departing from the scope of the invention.

### INDUSTRIAL APPLICABILITY

The present invention is applicable to, for example, carbon materials required to have a large specific surface area. Examples of the application include carbon materials used in fuel cells, carbon materials used in various batteries such as capacitors, secondary batteries, and flooded solar batteries, carbon materials of water purifying filters, gas adsorptive carbon materials, electron-emissive elements, and electron field emission displays.

1. A carbon nanotube composite, comprising a carbon nanotube assembly comprising multiple carbon nanotubes densely arranged in parallel oriented in the same direction, the carbon nanotube assembly having a high density of 70 mg/cm³ or more in a grown state.

2. A carbon nanotube composite, comprising:
a substrate having a surface; and
a carbon nanotube assembly which is mounted on a surface of the substrate and comprises multiple carbon nanotubes densely arranged in parallel oriented in the same direction along a direction upward from the surface, the carbon nanotube assembly having a high density of 70 mg/cm³ or more in a grown state.

3. The carbon nanotube composite according to claim 1, wherein the carbon nanotube assembly comprises a group of carbon nanotubes comprising the multiple carbon nanotubes arranged in parallel with a high orientation, the carbon nanotubes situated adjacent within a dimension of D, wherein D is the diameter of one carbon nanotube.

4. The carbon nanotube composite according to claim 1, satisfying a relationship Db>tb,
wherein:
Db is a diameter of a bundle of the carbon nanotubes, relative to a dimension in a direction perpendicular to an extending direction of carbon nanotubes; and
tb is a gap between adjacent carbon nanotube bundles, relative to a direction perpendicular to the extending direction of carbon nanotubes.

5. A method for producing the carbon nanotube composite according to claim 1, the method comprising:
forming a catalyst on a surface of a substrate; and
CVD-processing the surface of the substrate having the catalyst to form a carbon nanotube assembly by a carbon nanotube formation reaction,
wherein in the carbon nanotube formation reaction, a temperature of the substrate is increased from ambient temperature to a primary target temperature T1 ranging from 400 to 600° C. before formation of carbon nanotubes, and then the temperature is increased under control to a secondary target temperature T2 ranging from 600 to 1500° C. (T2≧T1) at a rate of 5 to 100° C./minute or maintained at a secondary target temperature T2 by introducing a carbon source gas, thereby causing carbon nanotube formation reaction by CVD-processing on the surface of the substrate having the catalyst.

6. The method according to claim 5, satisfying a relationship V1>V2,
wherein:
V1 is a temperature rising rate for primarily heating the substrate from ambient temperature to the primary target temperature T1 ranging from 400 to 600° C.; and
V2 is a temperature rising rate for secondarily heating the substrate to the secondary target temperature T2 (T2≧T1) ranging from 600° C. to 1500° C.

7. The carbon nanotube composite according to claim 2, wherein the carbon nanotube assembly comprises a group of carbon nanotubes comprising the multiple carbon nanotubes arranged in parallel with a high orientation, the carbon nanotubes situated adjacent within a dimension of D, wherein D is the diameter of one carbon nanotube.

8. The carbon nanotube composite according to claim 2, satisfying a relationship Db>tb,
wherein:
Db is a diameter of a bundle of the carbon nanotubes, relative to a dimension in a direction perpendicular to an extending direction of carbon nanotubes; and
tb is a gap between adjacent carbon nanotube bundles, relative to a direction perpendicular to the extending direction of carbon nanotubes.

9. A method for producing the carbon nanotube composite according to claim 2, the method comprising:
forming a catalyst on a surface of a substrate; and
CVD-processing the surface of the substrate having the catalyst to form a carbon nanotube assembly by a carbon nanotube formation reaction,
wherein in the carbon nanotube formation reaction, a temperature of the substrate is increased from ambient temperature to a primary target temperature T1 ranging from 400 to 600° C. before formation of carbon nanotubes, and then the temperature is increased under control to a secondary target temperature T2 ranging from 600 to 1500° C. (T2≧T1) at a rate of 5 to 100° C./minute or maintained at a secondary target temperature T2 by introduction of a carbon source gas, thereby causing carbon nanotube formation reaction by CVD-processing on the surface of the substrate having the catalyst.

10. The method according to claim 9, satisfying a relationship V1>V2,
wherein:
V1 is a temperature rising rate for primarily heating the substrate from ambient temperature to the primary target temperature T1 ranging from 400 to 600° C.; and
V2 is a temperature rising rate for secondarily heating the substrate to the secondary target temperature T2 (T2≧T1) ranging from 600° C. to 1500° C.
